(19) United States
(12) Patent Application Publication
(10) Pub. No.: US 2025/0137159 A1
(43) Pub. Date: May 1, 2025

(54) Stamping Surface Profile in Design Layer and Using Patterned Electroplating Protection Structure for Defining Electroplating Structure on Seed Layer

(71) Applicant: AT&S Austria Technologie & Systemtechnik AG, Leoben (AT)

(72) Inventors: Heinrich TRISCHLER, Eggersdorf (AT); Erich PREINER, St. Michael in Obersteiermark (AT); Marie SCALBERT, Leoben (AT)

(21) Appl. No.: 18/692,864

(22) PCT Filed: Oct. 28, 2022
(86) PCT No.: PCT/EP2022/080277

§ 371 Date: Mar. 18, 2024

(30) Foreign Application Priority Data
Oct. 29, 2021 (WO) PCT/IB2021/000940

(51) Int. Cl. C25D 7/12; C25D 5/00; C25D 5/02; H01L 21/768; H01L 23/528; H05K 3/24; H05K 3/46

(52) U.S. Cl. CPC C25D 7/123; C25D 5/022; C25D 5/605; H01L 21/76873; H01L 23/528; H05K 3/241; H05K 3/4644; H05K 2203/0723

(57) ABSTRACT

A method of manufacturing a component carrier, includes stamping a surface profile in a design layer, forming an electrically conductive seed layer on the stamped design layer, forming a patterned electroplating protection structure on portions of the seed layer apart from indentations of the profiled design layer, and electroplating an electroplating structure selectively on or above portions of the seed layer exposed with respect to the electroplating protection structure.

### CROSS REFERENCE TO RELATED APPLICATIONS

This application is a national stage application, filed under 35 U.S.C. § 371, of International Patent Application No. PCT/EP2022/080277, filed on Oct. 28, 2022, claiming priority of the International Patent Application No. PCT/IB2021/000940 filed on Oct. 29, 2021, all of them being incorporated by reference herein in their entirety.

### TECHNICAL FIELD

The disclosure relates to component carriers and to a method of manufacturing a component carrier.

### BACKGROUND OF THE DISCLOSURE

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. At the same time, component carriers shall be mechanically robust and electrically reliable so as to be operable even under harsh conditions.

Manufacturing electrically conductive connection structures of a component carrier in a simple way and with high precision is still difficult.

There is a need to form a component carrier with electrically conductive structures which can be manufactured in a simple way and with high precision.

### SUMMARY

In order to meet the need defined above, a component carrier and a method of manufacturing a component carrier according to the independent claims are provided.

According to an exemplary embodiment of the disclosure, a method of manufacturing a component carrier is provided, wherein the method comprises stamping a surface profile in a design layer, forming an electrically conductive seed layer on the stamped design layer, forming a patterned electroplating protection structure on portions of the seed layer apart from indentations of the profiled design layer, and electroplating an electroplating structure selectively on or above portions of the seed layer exposed with respect to the electroplating protection structure.

According to another exemplary embodiment of the disclosure, a component carrier is provided which comprises a design layer having a stamped surface profile, an electrically conductive seed layer selectively lining indentations of the stamped design layer, and an electroplating structure selectively on or above separated portions of the seed layer.

According to another exemplary embodiment of the disclosure, a component carrier is provided which comprises a mounting base and/or one or more components, a laminated layer stack mounted on or above the mounting base and/or on or above the one or more components, at least one design layer each having a stamped surface profile with indentations filled at least partially with an integrated wiring structure functioning as redistribution structure, wherein the at least one design layer is formed on the laminated layer stack, and one or more surface mounted components on the at least one design layer.

### Overview of Embodiments

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In the context of the present application, the term “design layer” may denote a layer being flexibly processable for designing substantially any desired surface profile extending therein and/or therethrough. Thus, any desired wiring design may be translated into a corresponding surface profile of the design layer so that filling created indentations in the design layer with electrically conductive material may lead to the predefined wiring design. Preferably, the design layer may be an initially at least partially uncured dielectric which may be cured during and/or after forming a predefined surface profile therein. The surface profile may then be rendered permanent. Hence, the design layer may be deformable before curing and may be non-deformable after curing. Preferably, the design layer may be made of a Nanoimprint Lithography (NIL) material. The design layer may or may not form part of a readily manufactured component carrier.

In the context of the present application, the term “stamping a surface profile in the design layer” may denote the process of imprinting or embossing a predefined surface pattern in the design layer. For instance, this may be accomplished by pressing a working mold (or working stamp) in the (in particular still) deformable design layer or by guiding a working mold along the (in particular still) deformable design layer. Such a working mold may have an inverse surface profile in comparison with the surface profile of the design layer being processed. During a development and manufacturing process, first a master mold may be manufactured, for example by gray scale lithography. Then the master mold may be replicated by stamping several times into a transparent silicone material or the like, and a master working mold may be generated. Finally, working molds may be made by copying the master working mold. The working molds may be used during mass production and imprinted on a panel surface.

In the context of the present application, the term “seed layer” may denote a thin metallic layer which may be formed by electroless plating. Electroless plating may denote a formation of the seed layer by a plating process which does not involve application of electricity to a structure to be plated with the seed layer. For example, electroless plating may involve formation of a chemical metal film as the seed layer. Additionally or alternatively, electroless plating may comprise forming the seed layer by sputtering.

In the context of the present application, the term “electroplating structure” may denote a metallic structure formed by electroplating. For electroplating, and in particular galvanic plating, of electrically conductive material on a seed layer formed by electroless plating, water-based solutions or electrolytes may be used which contain metal to be deposited as ions (for example as dissolved metal salts). An electric field between a first electrode (in particular an anode) and a preform of the component carrier to be manufactured as second electrode (in particular a cathode) may force (in particular positively charged) metal ions to move to the second electrode (in particular cathode) where they give up their charge and deposit themselves as metallic material on the surface of the through hole.

In the context of the present application, the term “electroplating protection structure” may denote a structure made of a material on which no (or at least no noteworthy amount of) metal can be deposited by electroplating. Thus, the electroplating protection structure may be an anti-plating dielectric structure and may particularly denote an electrically insulating structure made of a material on which plating of a metal is inhibited, disabled, or made impossible. This can be accomplished by providing the anti-plating dielectric structure from a non-adhesive or very poorly adhesive dielectric material with preferably hydrophobic properties on which electroplated metal does not adhere. Also, non-polarized properties of the electroplating protection structure may be advantageous. For example, the electroplating protection structure may comprise at least one of a group consisting of a release ink, polytetrafluoroethylene, and polyimide. More generally, any hydrophobic material may be appropriate for forming the electroplating protection structure. It is also possible that such a non-adhesive or poorly adhesive structure may be made of a waxy material or a suitable varnish.

According to an exemplary embodiment of the disclosure, a method of manufacturing a component carrier (such as a printed circuit board, PCB) is provided which advantageously uses a design layer being deformed by mechanically stamping (in particular using a working mold) so that a surface profile in accordance with a wiring structure to be formed can be created with high spatial resolution. After having formed a metallic seed layer on the created surface profile, an anti-plating protection structure may be formed on the seed layer (preferably only in the highest parts of the structure) so as to selectively expose one or more indentations with respect to the protection structure, whereas one or more non-stamped regions of the processed design layer apart from indentations may be covered with the protection structure. Advantageously, a subsequent electroplating process will then lead to a coverage only of an exposed region of the seed layer with electroplated metal, while no or substantially no electroplating of metal will occur on the protection structure. After a removal of the protection structure and seed layer portions beneath, a well-defined wiring pattern may be obtained in which electroplated metal is only present in the indentations, and not in regions in between. Highly advantageously, even complex wiring structures may thus be formed with very low manufacturing effort and excellent spatial accuracy. Advantageously, the provision of a patterned protection structure may prevent overplating in elevated regions of the design layer apart from the indentations during the electroplating process and may thus avoid the high effort and significant time consumption of a difficult polishing process for removing overplated metal. In particular, polishing processes such as CMP (chemical mechanical polishing) are difficult to execute on a panel format, i.e. for formation of PCB-type component carriers using a design layer on a panel level. Hence, manufacture of the component carriers may be carried out in a simple way and with high spatial accuracy.

According to another exemplary embodiment of the disclosure, a component carrier configured as hybrid package may be provided (see for example FIG. 33, FIG. 34 and FIG. 50). Thus, an arrangement, a system, or a package may be provided which may have a Nanoimprint Lithography (NIL)-based design layer as redistribution structure on a layer structure of a carrier (for instance an interposer or an IC-substrate). Moreover, a component may be mounted on the NIL-structure, wherein the carrier may be mounted on a further carrier. Such a hybrid package may combine the advantages of component carrier technology, of semiconductor technology, and of the technology of stamped design layers.

In the following, further exemplary embodiments of the component carriers and the method will be explained.

Next, advantageous material properties of the design layer will be summarized. The design layer may have one, any combination of at least two, or all of the properties mentioned in the following.

The glass temperature Tg of material (in particular of resin material) of the design layer may be in a range from 120° C. to 260° C. This may avoid undesired phase transitions of the design layer during processing and/or using the component carrier.

A value of the Young modulus below the glass temperature Tg may be in a range from 1000 MPa to 15000 MPa. A value of the Young modulus above the glass temperature Tg may be in a range from 60 MPa to 800 MPa. These properties may ensure that the material of the design layer is sufficiently mechanically strong for enabling a precise design of electrically conductive traces, vertical through connections, etc. in the design layer. At the same time, these properties may ensure that the material of the design layer has a sufficient elasticity to buffer thermal and/or mechanical stress.

A value of the coefficient of thermal expansion (CTE) below the glass temperature Tg may be in a range from 10 ppm/K to 40 ppm/K. A value of the coefficient of thermal expansion above the glass temperature Tg may be in a range from 50 ppm/K to 100 ppm/K. These values may suppress thermal stress in an interior of the component carrier.

A value of the fracture strain below the glass temperature Tg may be at least 2%. This may lead to advantageous mechanical properties of the design layer and a correspondingly manufactured component carrier.

A value of the chemical shrinkage may be not more than 3%. Consequently, shrinkage-based curing stress in an interior of the component carrier may be avoided.

A Dk value of the material of the design layer (in particular of resin thereof) may be not more than 3. A Df value of the material of the design layer (in particular of resin thereof) may be not more than 0.003. As a result, an obtained component carrier may have excellent properties in terms of high-frequency behavior.

A number of press cycles which the material of the design layer may withstand may be in a range from 1 to 10. A number of reflow tests which the material of the design layer may withstand may be at least 6. This may allow to manufacture a component carrier using a design layer with a stack thickness being selectable over a sufficiently broad range.

The material of the design layer may be characterized by a peel test on copper of at least 600 N/m. Moisture absorption by the material of the design layer may be not more than 0.1%. A desmear rate of the material of the design layer may be at least 0.006 g/min. The material of the design layer may be characterized by a UL listing (in accordance with the industrial standard IEC/DIN EN 60695-11-10 and -20 in the latest version being in force at the priority date of the present application) of V1 to V0 (which may ensure safety against flammability). The mentioned material properties may simplify processing of the design layer.

Advantageously, the design layer may comprise resin and (preferably inorganic) fillers (such as filler particles). Optionally, one or more additives may be included in the material of the design layer for functionalizing the latter.

Preferably, the inorganic fillers may be in a crystalline state. Furthermore, the inorganic fillers may be encapsulated. An average size (to be calculated according to an arithmetic average) of the inorganic fillers may be smaller than 0.1 μm. For example, the inorganic fillers may be made of fused silicon oxide. The inorganic filler particles may be plasma etchable. A weight percentage of the filler particles, in relation to an entire weight of the material of the design layer, may be up to 95 weight %.

A further constituent of the design layer may be resin. Epoxy resin, poly(p-phenylene ether) (PPE), Bisbenzocyclobutene (BCB), Polybenzoxabenzole (PBO), and/or polyimide may be used. A chloride content of the resin may be below 30 ppm. Advantageously, no salt formation should occur during the processing of the resin. Moreover, a high cross-linking capability of the resin may be advantageous. A low porosity may be preferred to avoid undesired phenomena such as cracks, migration, etc.

In an embodiment, a continuous layer of the protection structure may be formed on the seed layer and may be subsequently patterned, for instance by lithography and etching. However, it may be preferred to form a patterned protection structure by using a simple non-selective process, such as, for example a flat surface being coated completely with protection ink. Thereafter, use can be made of different NIL resist heights (i.e. regions of different height of the profiled design layer) that are present after NIL imprinting (i.e. after stamping the design layer)—by coating only the top layer of the NIL imprinted resist (i.e. profiled design layer) by a short contact between the ink coated surface and the NIL resist surface. By taking this measure it may be ensured that the protection structure is formed only on the highest regions of the profiled design layer.

In an embodiment, the stamping comprises forming tapering indentations in the design layer. Correspondingly, the electroplating structure may have tapering sidewalls. Advantageously, stamping of the design layer may be accomplished by a working mold (for instance a glass plate with a surface profile on one main surface) deforming the design layer for forming a surface profile therein being inverse to a surface profile of the working mold. After the stamping process, the working mold may be removed again from the design layer. Under undesired circumstances, it may be difficult to remove the working mold from the design layer after stamping without damaging the formed surface profile due to adhesion between design layer and working mold. However, it has been surprisingly found that providing the working mold with tapering protrusions corresponding to inverse tapering indentations in the design layer significantly reduces the tendency of the working mold of adhering to the profiled design layer when removing the working mold after stamping. Furthermore, such a tapering geometry may also reduce the risk of defects in the processed design layer.

In an embodiment, the stamping comprises forming indentations of different depth and/or different length in the design layer. Correspondingly, the electroplating structure (optionally in combination with a portion of the seed layer and/or a metallic base structure) may form or may form part of sub-structures of different depth and/or different length in the design layer. For instance, at least one first indentation formed in the design layer may extend through the entire design layer and may thereby form a through hole. Such a through hole may, when filled with plated metal, form an electrically conductive through connection (such as a via) in the readily manufactured component carrier. For example, at least one second indentation formed in the design layer may extend through only part of the thickness of the design layer and may thereby form a blind hole. Such a blind hole may, when filled with plated metal, form a horizontally extending trace in the readily manufactured component carrier. Advantageously, a horizontal trace may have a larger length than a vertical through connection. With the described manufacturing architecture, a design layer may be formed with two or more indentations extending up to different vertical positions and/or extending along different horizontal extensions. Consequently, even complex horizontal and/or vertical wiring structures may be defined precisely and in a simple way. In particular, this may also make it possible to create three-dimensionally curved wiring structures.

In an embodiment, the stamping comprises forming trace-shaped and/or via-shaped and/or combined trace-and-via-shaped indentations in the design layer. Accordingly, the electroplating structure (optionally in combination with a portion of the seed layer and/or a metallic base structure) may form or form part of trace-type and/or via-type sub-structures, or a combination thereof. Highly advantageously, both electrically conductive traces and vertical through connections may be formed simultaneously and thereby quickly with miniature dimensions in a common design layer.

In an embodiment, the method comprises curing the design layer, in particular simultaneously stamping and curing the design layer. During the NIL process, the stamping and curing may occur simultaneously (once one stamps, one may expose the structure, to prevent the resist from flowing apart). During stamping, the design layer is preferably freely deformable by a mechanical impact, which allows to stamp indentations in the design layer by a working mold in accordance with a desired wiring pattern. After stamping, the created surface profile shall remain permanent at least in certain embodiments, i.e. the processed design layer shall be converted into a non-deformable state. This can be accomplished by curing the design layer. For instance, when the design layer comprises at least partly uncured resin, curing may be accomplished by the application of thermal energy and/or mechanical pressure, which may trigger curing processes such as cross-linking, polymerization, etc. Supply of curing energy may be accomplished by irradiation of the design layer with electromagnetic radiation of an electromagnetic radiation source, preferably ultraviolet (UV) radiation. Highly advantageously, curing of the design layer may be accomplished during stamping and further advantageously by a working mold itself. For instance, a light source (such as a UV lamp) may be integrated in the working mold so that light-triggered (in particular UV-triggered) curing may be carried out during the process of stamping.

In an embodiment, the method comprises removing the electroplating protection structure after the electroplating. For instance, a resist layer used as electroplating protection structure may be removed after electroplating by etching or stripping.

In an embodiment, the method comprises removing portions of the seed layer which have been exposed as a result of the removing of the electroplating protection structure. Removal of the patterned electroplating protection structure after the electroplating may expose portions of the seed layer which have been initially covered by the electroplating protection structure. The latter mentioned portions of the seed layer may be subsequently removed for separating and thereby electrically decoupling individual wiring structures in the indentations.

In an embodiment, the method comprises forming the design layer on or above a carrier covered with a release layer and detaching the profiled design layer with sections of the seed layer and the electroplating structure from the carrier at the release layer. Preferably, the carrier may comprise or may consist of glass. For example, such a temporary carrier may be a support plate, for instance made of glass or FR4. Preferably, the mentioned release layer may have non-adhesive or poorly adhesive properties. Examples for materials of the release layer are a release ink, polytetrafluoroethylene, polyimide, a waxy material or a suitable varnish. This allows detaching the readily manufactured component carrier or a preform thereof from the temporary carrier at the end of a manufacturing process.

In another embodiment, the method comprises forming the design layer on the carrier, not necessarily comprising a release layer. As mentioned, the carrier may be a temporary carrier which may be removed at the end of the manufacturing process. However, alternatively, the carrier may form part of the component carrier, in which case the carrier is not removed from the design layer. Such a carrier may also be—in particular directly—connected to the design layer (i.e. may also be provided without release layer in between). Such a carrier may be an insulating layer (e.g. comprising resin) with or without an (in particular patterned) electrically conductive wiring thereon. This electrically conductive wiring allows a direct electric connection from the carrier to the metallic base structure. A permanent carrier forming part of a component carrier according to an exemplary embodiment of the disclosure may be made preferably of glass. It is specifically preferred that such a component carrier with glass carrier is configured as interposer. Hence, in particular when glass is used as insulating layer or insulating carrier, it may be advantageous that an additive build-up with NIL is used for manufacturing an interposer. As interposers can be advantageously made with glass as insulating material, the carrier structure (or further build-up structure) can be advantageously used for a NIL process.

In an embodiment, the method comprises forming a build-up based on the detached profiled design layer with sections of the seed layer and the electroplating structure. It is also possible that the method comprises forming a build-up on the profiled design layer with sections of the seed layer and the electroplating structure. Accordingly, the component carrier may comprise a build-up on one or both opposing sides of the profiled design layer with the portions of the seed layer and the electroplating structure. Hence, after or without detaching the profiled and metallized design layer from the carrier, a further build-up of the component carrier may be formed.

Preferably, the build-up comprises at least one laminated printed circuit board-type layer stack. Formation of such a build-up may involve processes such as laminating additional electrically conductive layer structures (for example copper foils) and/or electrically insulating layer structures (for instance prepreg sheets) to one or both opposing main surfaces of the separated profiled and metallized design layer. However, galvanic plating of copper layers may be preferred in certain embodiments. The readily manufactured component carrier may then be a hybrid of the profiled and metallized design layer and the PCB-type stack(s) of laminated layer structures.

In an embodiment, the method comprises applying an adhesion promoter (such as an adhesion promoting layer) on the stamped design layer before forming the electrically conductive seed layer. Such an adhesion promoter may for instance comprise silane and may be deposited as a thin layer before creating the seed layer. This may improve the interlayer adhesion of the obtained structure and may therefore suppress undesired phenomena such as delamination in the readily manufactured component carrier. Additionally or alternatively to an adhesion promoter, it is also possible to apply a barrier layer which may function as a barrier for connected materials.

In an embodiment, the method comprises removing, in particular by etching, residues of the design layer in at least one bottom region of the indentations of the profiled design layer. In particular when intending to form through holes extending through the entire design layer, it may happen that, after the stamping, a thin skin of design layer material remains at the bottom of the indentation which shall form a through hole. During forming a seed layer, such an artifact may lead to an undesired electric isolation by the remaining dielectric skin. In order to avoid such phenomena, it may be advantageous to treat the stamped design layer (in particular prior to seed layer formation) by an etching process to remove residues from indentations of the design layer after stamping.

In an embodiment, the method comprises arranging and processing the design layer on an electrically conductive layer so that at least one surface portion of the electrically conductive layer is exposed with respect to the stamped design layer. Correspondingly, the design layer of the component carrier may be arranged on an electrically conductive layer so that at least one surface portion of the electrically conductive layer is exposed with respect to the design layer at at least one of the indentations. For example, such an electrically conductive layer may be a copper foil or another seed layer underneath the design layer. By exposing one or more portions of the electrically conductive layer by stamping the design layer, it is possible to easily define said one or more portions as selective surface for subsequent electroplating.

In an embodiment, the method comprises forming a metallic base structure selectively on the at least one exposed surface portion of the electrically conductive layer and in the corresponding at least one indentation of the profiled design layer. Accordingly, the component carrier may comprise a metallic base structure in a bottom of a corresponding indentation of the design layer. Thus, the one or more exposed surface portions of the electrically conductive layer may define where the metallic base structure can be formed by electroplating, in particular galvanic plating. This may be accomplished by applying an electric voltage to the electrically conductive layer in an appropriate galvanic path.

In an embodiment, the electrically conductive seed layer may also be formed partially on the metallic base structure. Such an embodiment is shown for instance in FIG. 15.

In an embodiment, the method comprises subsequently electroplating the electroplating structure on the metallic base structure. Correspondingly, at least a portion of the electroplating structure of the component carrier may be arranged on top of the metallic base structure. Descriptively speaking, at least one further electroplating structure may be formed as the metallic base structure by at least one further electroplating stage, in particular by galvanic plating. The separate formation of the metallic base structure and the electroplating structure may also allow to create a multi-metal structure in an indentation of the profiled design layer. Hence, it may be possible to fill an indentation with at least two different metallic materials, each of which being functionally adjustable separately.

In an embodiment, the method comprises forming the metallic base structure to comprise a bottom-sided sub-structure and a top-sided substructure. Correspondingly, the metallic base structure may comprise a bottom-sided sub-structure and a top-sided substructure in the readily manufactured component carrier. For reliably filling deep indentations with metallic material, it may be preferable to execute the filling process with at least two electroplating stages for forming the metallic base structure.

In an embodiment, the method comprises forming at least part of the metallic base structure by electroplating. Preferably, the metallic base structure may be formed by galvanic plating.

In an embodiment, the method comprises forming a metallic base structure in the corresponding at least one indentation of the profiled design layer. While in one embodiment, a bottom of a respective indentation may be formed by an electrically conductive layer which allows formation of the metallic base structure by electroplating, it is also possible that the metallic base structure is formed on a purely dielectric surface delimiting a respective indentation by electroless plating. The metallic base structure may partially fill a respective indentation.

In an embodiment, the method comprises forming the metallic base structure at least partially from a solderable metallic material, in particular comprising or consisting of tin. Correspondingly, the component carrier may comprise a metallic base structure with a solderable metallic material, in particular comprising or consisting of tin. In this context, the term solderable metallic material may denote a material which is capable of forming a solder connection, i.e. a solder such as tin or a solder alloy. Advantageously, at least partially filling an indentation in the stamped design layer with a solderable metallic material may allow to solder-connect the metal-filled design layer with a connection body, such as a component (for example a semiconductor chip or another electronic component) or a mounting base (for example a further component carrier, such as a printed circuit board or an integrated circuit substrate) when exposing the solderable metallic material. Such an approach may significantly simplify the establishment of a solder connection between the component carrier and a connection body.

In an embodiment, the method comprises forming the solderable metallic material on at least part of a bottom surface of the at least one indentation of the profiled design layer. Advantageously, subsequently exposing the bottom surface by removing a carrier from the design layer may automatically expose a solderable metallic material. Formation of a solder connection may then be carried out without additional effort.

In an embodiment, the method comprises forming the metallic base structure partially from the solderable metallic material and partially from a metal, in particular copper, with a higher electric conductivity than the solderable metallic material. Correspondingly, the metallic base structure of the component carrier may be formed partially from the solderable metallic material (preferably comprising tin) and partially from a metal (preferably copper) with a higher electric conductivity than the solderable metallic material. Advantageously, the described approach combines a direct solderability of the metallic base structure—when the solderable metallic material is exposed—with a low ohmic configuration thanks to the metal with higher electric conductivity.

In an embodiment, the method comprises forming the solderable metallic material and the metal with the higher electric conductivity both on at least part of a bottom surface of the corresponding at least one indentation of the profiled design layer, in particular so that the solderable metallic material at least partially laterally surrounds the metal with the higher electric conductivity. Correspondingly, the solderable metallic material of the component carrier may at least partially laterally surround the metal with the higher electric conductivity. Such an approach is shown for instance in FIG. 43 and allows to provide, at the same vertical level, a solderable material and a non-solderable further metallic material with very low ohmic resistance. This may ensure a reliable electrically conductive connection with little contact resistance and low losses.

In an embodiment, the method comprises detaching the profiled design layer with the metallic base structure from a carrier to thereby expose the solderable metallic material to prepare subsequent soldering. Such a detachment may be carried out for instance by removing the carrier by etching and/or grinding. It is also possible that the carrier is detached from the metal-filled design layer at a release layer (having intentionally poor adhesion) arranged between carrier and design layer. This may automatically expose the metallic base structure and in particular a solderable material thereof. Briefly, an exposed solder cap (such as an exposed tin cap) may be obtained which allows the creation of a direct solder connection with any desired connection body.

In an embodiment, the method comprises creating a solder connection between the exposed solderable metallic material and a connection body, in particular a mounting base or a component. Correspondingly, the component carrier may comprise a connection body, in particular a mounting base or a component, being soldered on the solderable metallic material. In particular, the solderable metallic material may mechanically and electrically couple the connection body with the electroplating structure in the indentation(s).

In an embodiment, the method comprises forming a further design layer on or above the design layer, stamping a further surface profile in the further design layer for forming at least one further indentation to thereby expose at least part of the electroplating structure, and configuring the further design layer as a solder mask and/or underfill. Correspondingly, the component carrier may comprise a further design layer configured as a solder mask and/or underfill on or above the design layer and having a further stamped surface profile forming at least one further indentation to thereby expose at least part of the electroplating structure. Descriptively, a further stamped design layer may function as a solder mask or solder resist. Solder resist material may protect the component carrier or part thereof against oxidation or corrosion, in particular may protect surface portions containing a metal such as copper. Furthermore, a solder resist may optionally define one or more surface portions of a component carrier on which no solder material shall and will attach. Briefly, the material of a solder resist may be selected so that solder material will not attach and remain on surface regions of a stack of a component carrier which are covered by the solder resist. Forming a solder mask or an underfill (for instance provided at the bottom side of a semiconductor chip to be surface mounted on the component carrier) from a stamped design layer is a particularly simple and precise approach.

In an embodiment, the method comprises configuring at least part of the electroplating structure beneath the further design layer as a redistribution structure or as part thereof. Correspondingly, at least part of the electroplating structure beneath the solder mask may be configured as a redistribution structure. In the context of the present application, the term “redistribution structure or layer” may particularly denote one or more patterned electrically conductive layers which function as an electric interface between larger dimensioned electric connection structures (in particular relating to component carrier technology, more particularly printed circuit board technology or integrated circuit substrate technology) and smaller dimensioned electric connection structures (in particular relating to semiconductor chip technology). Integrating metallic elements of a redistribution structure in a further design layer which functions as well as solder mask provides a high degree of functionality combined with a compact design.

In an embodiment, the method comprises forming a surface finish and/or a solderable metallic structure in the at least one further indentation and on (in particular electrically connected with) or above the exposed electroplating structure. Correspondingly, the component carrier may comprise a surface finish and/or a solderable metallic structure in the at least one further indentation and on or above the exposed electroplating structure. The surface finish may provide the function to protect exposed electrically conductive layer structures and enable a joining process with one or more components, for instance by soldering. For instance, said surface finish may be Organic Solderability Preservative (OSP), Electroless Nickel Immersion Gold (ENIG), Electroless Nickel Immersion Palladium Immersion Gold (ENIPIG), etc. Additionally or alternatively to the formation of a surface finish in indentations of the further design layer, the indentations of the further design layer being configured as solder mask may also be filled with a solderable material, for instance comprising tin. This simplifies a subsequent solder connection process in a compact way.

In an embodiment, the method comprises removing the design layer before completing manufacture of the component carrier. In such an embodiment, the design layer does not form part of the readily manufactured component carrier, i.e. may be a temporary design layer. This may be advantageous in a configuration in which highly homogeneous material properties of the component carrier, such as a printed circuit board (PCB), are desired. This may make it possible to constitute for instance the entire dielectric material of the component carrier from prepreg or FR4.

Alternatively, the design layer may remain part of the readily manufactured component carrier, i.e. may be a permanent design layer. It may then be possible to adjust the material properties of the design layer so that a component carrier with high electric, mechanical and/or thermal reliability is obtained. This may allow to suppress undesired phenomena such as warpage, delamination, and mechanical and/or thermal stress. For example, this may be accomplished by configuring the design layer with material properties as described herein.

In an embodiment, the electroplating structure forms or forms part of at least one sub-structure having a depth-to-diameter ratio (which may also be denoted as aspect ratio) of larger than 1, and in particular of larger than 1.5. With conventional laser drilling, the aspect ratio is strongly limited for technical reasons. However, when defining indentations by stamping a still uncured deformable design layer with a correspondingly shaped working mold, there are substantially no limits in terms of aspect ratio. Thus, indentations with an aspect ratio of more than 1, for instance as large as 2 or more, may be created in a simple and reliable way by stamping a design layer.

In an embodiment, a roughness Ra of a surface, in particular a sidewall surface, of the design layer delimiting the surface profile is not more than 100 nm, in particular not more than 50 nm. Ra denotes the arithmetic mean value of all distances of a profile from a centerline. For instance, the measurement or determination of roughness Ra may be carried out according to DIN EN ISO 4287:2010. The mentioned roughness values may lead to a low loss transmission of radiofrequency signals through the wiring structure(s), since no excessive surface roughness deteriorates signal propagation under consideration of the skin effect. According to the skin effect, an electric signal with a high-frequency, for instance in the gigahertz range, does not propagate over an entire cross-section of a conductor, but propagates substantially only within a skin-like surface portion thereof. This may conventionally cause significant signal losses with rough surfaces. Without wishing to be bound to a specific theory, it is presently believed that such signal losses may result from an additional electric resistance or impedance which the traveling radiofrequency signal suffers as a consequence of a rough surface. Advantageously, such signal losses can be prevented or at least strongly suppressed when ensuring a low roughness of electrically conductive wiring structures of a component carrier as a result of the formation of indentations in a design layer by stamping.

In an embodiment, the component carrier comprises at least one component being electrically connected to the electroplating structure. Such a component, for instance an electronic component such as a semiconductor chip, may be surface mounted on the design layer with integrated wiring structure.

In an embodiment, the component carrier further comprises a further design layer in which a further surface profile is stamped, a further electrically conductive seed layer selectively lining further indentations of the stamped further design layer, and a further electroplating structure selectively on or above separated portions of the further seed layer, wherein the further profiled design layer with the further electrically conductive seed layer and the further electroplating structure are arranged on the profiled design layer with the electrically conductive seed layer and the electroplating structure. Hence, a plurality of design layers, each with integrated wiring structure(s), may be vertically stacked to form more complex three-dimensional arrangements of wiring structures. Hence, this may make it possible to create even sophisticated or complex wiring architectures in the component carrier in a straightforward way. Working molds of different stacked design layers may be the same or may be different.

In an embodiment, the further electrically conductive seed layer and the further electroplating structure are connected in a landless way with the electrically conductive seed layer and the electroplating structure. Advantageously, pads between stacked design layers, each formed with integrated wiring structure(s), may be dispensable in view of the high spatial accuracy of the definition of the wiring structures by stamping using a corresponding working mold. In particular, a correspondingly formed electroplating structure may comprise three-dimensionally curved substructures.

In an embodiment, the component carrier comprises at least one component, such as an electronic component like a semiconductor chip, mounted on the design layer by a connection structure (for example by one of a solder structure and a thermal compression bonding structure) arranged between the component and the design layer. For example, a solder structure may be constituted by solder balls applied to the component or on top the design layer. As an alternative to soldering, surface mounting of one or more components may also be accomplished by sintering, gluing, etc. Also, thermal compression bonding is an option for mounting a component on the stack of the component carrier.

In an embodiment, the component carrier comprises two components arranged side-by-side on the design layer and being electrically coupled with each other by electrically conductive connection structures at and/or lateral from a protrusion of the design layer. Highly advantageously, the design layer may be synergistically used for horizontally connecting laterally adjacent components mounted on the design layer. For this purpose, the surface profile of the design layer may comprise a central protrusion protruding vertically beyond a horizontal surface of the rest of the design layer. Side portions of each of the two components to be electrically connected with each other may then be mounted on corresponding portions of the central protrusion, so that electrically conductive connection structures on the protrusion between the protrusion and each of the surface mounted components may then establish an electric coupling between the components. Additionally or alternatively, such electrically conductive connections may be formed on surface portions beneath the components and apart from the central protrusion and may extend between the design layer apart from the central protrusion and each of the components. By the described component-to-component connection architecture, a conventionally used silicon bridge may be omitted and may be replaced by a central protrusion of the design layer. This renders the interconnection within a component carrier with surface mounted components easy.

In the following, several additional aspects of a component carrier configured as hybrid package (see in particular the embodiments of FIG. 33, FIG. 34, and FIG. 50) will be explained.

In an embodiment, the mounting base is a motherboard, a printed circuit board or an integrated circuit substrate. Such a mounting base (or additionally or alternatively a bottom-sided component, such as a semiconductor chip) may form the base of the component carrier.

In an embodiment, the laminated layer stack is a printed circuit board, an integrated circuit substrate, or an interposer. Hence, the laminated layer stack may be a laminated printed circuit board layer stack.

In an embodiment, the one or more surface mounted components are electrically connected to the at least one design layer by solder structures. Such solder structures may be integrally formed as part of the wiring structures of the design layer or may be attached externally.

In an embodiment, the one or more surface mounted components are encapsulated in a mold compound. A plurality of surface mounted components may be encapsulated by the same mold compound structure.

In an embodiment, the at least one design layer is a stack of design layers. Hence, two or more design layers may be stamped, metallized, and stacked on top of each other, which allows the formation of even complex redistribution structures.

In an embodiment, the component carrier is configured as a hybrid package. Descriptively speaking, the component carrier may combine component carrier technology with semiconductor technology and stamped design layer technology.

In an embodiment, the integration density of wiring structures in the at least one design layer is larger than the integration density of wiring structures in the laminated layer stack. A line space ratio may thus be smaller in the design layer compared with the laminated layer stack.

In an embodiment, the component carrier comprises at least one further design layer each having a stamped surface profile with indentations filled at least partially with a further integrated wiring structure, wherein the at least one further design layer is formed between the mounting base and/or the one or more components on the one hand and the laminated layer stack on the other hand (see for example FIG. 34). If desired, one or more additional design layers may be sandwiched in the stack of hybrid structures.

In an embodiment, one main surface of the design layer has a higher surface roughness Ra than a corresponding main surface of the at least one further design layer. Surface roughness may be calculated measuring the average of surface heights and depths across the surface. This measurement is commonly indicated as “Ra” for “Roughness Average”, as known by those skilled in the art. In particular, one main surface may face away from the stamped surface profile of the design layer. Thus, one of the surfaces of the stamped layers may have a rougher surface as the other stamped layers. This can be achieved for example when starting with a copper foil as carrier or in case NIL-layers are added on an IC-substrate or a PCB build-up structure. The rougher surface increases the adhesion between the design layer and the adjacent structure (e.g. a copper foil) and thus prevents cracks between these layers and ensures a high reliability of the component carrier.

Specifically, the design layer material is configured for being used for prepolymer composition, characterized in that it is used for continuous structuring and in-situ UV curing in a NIL imprint process, preferably in a roll-to-plate process, which stays in a final build-up.

Specifically, the design layer material is configured for being used as an etching production during an etching process for structuring a surface.

According to a further exemplary embodiment the design layer has an adhesion of more than 600 Nm. Adhesion is the tendency of dissimilar particles or surfaces to cling to one another. The forces that cause adhesion may be intermolecular forces responsible for the function of various kinds of stickers and sticky tape fall into the categories of chemical adhesion, dispersive adhesion, and diffusive adhesion.

According to a further exemplary embodiment the design layer comprises temperature resistance between 200° C. and 300° C., in particular 230° C. to 260° C. The design layer may be in particular a cured cross-linked resist material having the temperature resistance between 230° C. to 260° C. The higher the cross-linking, the higher the modulus-depending on used base oligomers.

According to a further exemplary embodiment, the design layer comprises material of a flame retardancy class 4 (FR4). FR4 may be a composite material composed of woven fiberglass cloth with an epoxy resin binder that is flame resistant (self-extinguishing). FR-4 glass epoxy is a high-pressure thermoset plastic laminate grade with good strength to weight ratios. With near zero water absorption, FR-4 is used as an electrical insulator possessing considerable mechanical strength.

According to a further exemplary embodiment, the design layer comprises material having a glass-transition temperature between 120° C. and 200° C., in particular between 135° C. and 170° C.

According to a further exemplary embodiment, the design layer has a (Young) modulus below a glass-transition temperature (in the fully cured stage) of 1000 MPa to 14000 MPa, in particular 5000 MPa to 13000 MPa.

According to a further exemplary embodiment, the design layer has a (Young) modulus above a glass-transition temperature (i.e. in a reflow state) of 60 MPa to 800, in particular 100 MPa to 600 MPa. The glass-liquid transition is the gradual and reversible transition in amorphous materials (or in amorphous regions within semicrystalline materials) from a hard and relatively brittle glassy state into a viscous or rubbery state as the temperature is increased. An amorphous solid that exhibits a glass transition is called a glass. The reverse transition, achieved by supercooling a viscous liquid into the glass state, is called vitrification. The glass-transition temperature Tg of a material characterizes the range of temperatures over which this glass transition occurs. It is lower than the melting temperature.

These properties may ensure that the material of the design layer is sufficiently mechanically strong for enabling a precise design of electrically conductive traces, vertical through connections, etc. in the design layer. At the same time, these properties may ensure that the material of the design layer has a sufficient elasticity to buffer thermal and/or mechanical stress.

According to a further exemplary embodiment, the design layer has a thermal expansion coefficient below a glass-transition temperature of 10 ppm/K to 40 ppm/K, in particular 20 ppm/K to 40 ppm/K. These values may suppress thermal stress in an interior of the component carrier.

According to a further exemplary embodiment, the design layer has a thermal expansion coefficient above a glass-transition temperature of 50 ppm/K to 100 ppm/K, in particular 60 ppm/K to 85 ppm/K. These values may suppress thermal stress in an interior of the component carrier. The higher the value of the thermal expansion coefficient (CTE) above Tg, the higher the reliability issue. The design layer may comprise non-woven glass fibers such that thermal expansion occurs in all directions. The thermal expansion coefficient is also driven by the amount of fillers. The thermal expansion coefficient decreases if the amount of filler increases. The design layer may have a filler content of 80% filler.

According to a further exemplary embodiment, the design layer is formed with a fracture strain below a glass-transition temperature of is 2%. This may lead to advantageous mechanical properties of the design layer and a correspondingly manufactured component carrier.

According to a further exemplary embodiment, the design layer is formed with a chemical shrinkage below 3%. Consequently, shrinkage-based curing stress in an interior of the component carrier may be avoided.

According to a further exemplary embodiment, the design layer is formed with a moisture absorption below 0.1%, and/or a desmear rate below 0.006 g/min of 3%.

A Dk value of the material of the design layer (in particular of resin thereof) may be not more than 3, specifically for high frequency applications. A Df value of the material of the design layer (in particular of resin thereof) may be not more than 0.003, specifically for high frequency applications. As a result, an obtained component carrier may have excellent properties in terms of high-frequency behavior. If the filler content increases, the values for Dk and Df increase as well.

A number of press cycles which the material of the design layer may withstand may be in a range from 1 to 10. A number of reflow tests which the material of the design layer may withstand may be at least 6. This may allow to manufacture a component carrier using a design layer with a stack thickness being selectable over a sufficiently broad range. The material of the design layer may be characterized by a peel test on copper of at least 600 N/m. A press cycle of the design layer may withstand from 6 up to 10 times.

A desmear rate of the material of the design layer may be at least 0.006 g/min. The material of the design layer may be characterized by a UL listing (in accordance with the industrial standard IEC/DIN EN 60695-11-10 and -20 in the latest version being in force at the priority date of the present application) of V1 to V0 (which may ensure safety against flammability). The mentioned material properties may simplify processing of the design layer. The design layer comprises aromatic hydrocarbons, such as PPE (poly(p-phenylene ether), BCB (Benzocyclobutene), Epoxy and/or halogenated polyimide. Specifically, the design layer is configured for being used in a SLID soldering process, wherein temperatures of 25° C. for 0.5 to 1 hour are applied.

According to a further exemplary embodiment, the design layer comprises a fully cured polymer based on at least one of the following group comprising epoxies, acrylates, polyphenylenether, polyimide, polyamide and polyetheretherketon, poly(p-phenylene ether) (PPE), Bisbenzocyclobutene (BCB), and/or Polybenzoxabenzole (PBO).

Specifically, a combination of the oligomers listed above may be used for a (specifically permanent) design layer (i.e. an UV-NIL resist). For example, a combination of BCB, PPE and SU8 loaded can be used with a high amount of more than 80% of encapsulated inorganic, round shape SiO₂ nanofillers and a halogen-free material.

For example, BCB (Divinylsiloxane-bis-benzocyclobutene (DVS-bis-BCB, or BCB), e.g. CYCLOTENE™ DuPont Series advanced electronic resins) are photopolymers. These polymers are derived from B-staged bisbenzocyclobutene (BCB) chemistry.

For example, PPE (e.g. Sabic NORYL SA9000 resin) is a modified, low molecular weight, bi-functional oligomer based on polyphenylene ether (PPE) with vinyl end-groups (used in Megtron 6 & 7 Materials).

For example, SU-8 (e.g. Kayaku Advanced Materials SU-8) is a high contrast, epoxy-based photoresist designed for micromachining and other microelectronic applications.

A chloride content of the resin may be below 30 ppm. Specifically, the design layer may be almost free of halogens (e.g. less than 30 ppm) which are ionic and not bonded with a polymer. The halogens may be washed out with multiple water wash steps.

Advantageously, no salt formation should occur during the processing of the resin. Moreover, a high cross-linking capability of the resin may be advantageous. A low porosity may be preferred to avoid undesired phenomena such as cracks, migration, etc.

According to a further exemplary embodiment, the design layer comprises polymer- or oligomer-based building blocks, wherein at least one of the building blocks is based on one of the above-mentioned polymers.

According to a further exemplary embodiment, the design layer at least one of the building-blocks has at least one functional group covalently bond to another one of the least one building block. The covalently bound functional group is responsible for the cross-linking connection.

According to a further exemplary embodiment, the at least one functional group is selected from one of the group comprising a thiol group selected from the group of 3-mercaptopropionates, 3-mercaptoacetates, thioglycolates and alkylthiols, and/or a double bond selected from the group of acrylates, methyl acrylates, vinyl ethers, allyl ethers, propenyl ethers, alkenes, dienes, unsaturated esters and allyl triazines, allyl isocyanates and N-vinyl amides.

According to a further exemplary embodiment, the design layer comprises a prepolymer having at least one photoinitiator, contained in an amount of 0.1 wt. % to 10 wt. %, in particular 0.5 wt. % to 5 wt. %.

According to a further exemplary embodiment, the design layer is in particular a fully cured resin, wherein the design layer further comprises filler particles such as in an amount of 1 wt. % to 10 wt. %, in particular 1 wt. % to 3 wt. %.

According to a further exemplary embodiment, the filler particles comprise inorganic fillers, wherein the inorganic fillers are in a crystalline state and in particular encapsulated. The inorganic fillers may be nanofillers which can be coated to avoid agglomeration and reduce thixotropy. Porous fillers may have lower Dk because of air but they can absorb chemistry. Therefore, porous fillers have a hydrophobic silane coating as it is the case in Rogers 3000 materials, at the same time mixing of fillers in the resin matrix is easier. Halogenated organics, hydrophobic polymers and covalent bonded halogen can be used for the fillers so that a high flame retardant can be achieved. The design layer may comprise high inorganic filler with an aromatic content. The inorganic fillers may have a round smooth shape, which is better than needles shape.

According to a further exemplary embodiment the filler particles comprise a size (e.g. an average size to be calculated according to an arithmetic average) of less than 0.1 μm.

According to a further exemplary embodiment, the filler particles comprise Talcum (i.e. a layered silicate), Zeolite and/or fused SiO₂. SiO₂ or Zeolite nanofiller usually agglomerate but with coating this agglomeration can be reduced and also tixotrophy may be reduced.

According to a further exemplary embodiment, the filler particles are of plasma etchable material.

According to a further exemplary embodiment, the design layer comprises less than 95% (weight percentage) filler particles, in particular 80% to 95% filler particles, in relation to an entire weight of the material of the design layer. More filler particles cause less shrinking of ink during UV-curing, for example, and causes better CTE at the same time. Furthermore, a better flame-retardant property is achieved at the same time.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. In particular a naked die as an example for an electronic component can be surface mounted on a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). A printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, Melamine derivates, Polybenzoxabenzole (PBO), bismaleimide-triazine resin, polyphenylene derivate (e.g. based on polyphenylenether, PPE), polyimide (PI), polyamide (PA), liquid crystal polymer (LCP), polytetrafluoroethylene (PTFE), Bisbenzocyclobutene (BCB), and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular coated with supra-conductive material or conductive polymers, such as graphene or poly(3,4-ethylenedioxythiophene) (PEDOT), respectively.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be surface mounted on the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer, or a further component carrier, for example in a board-in-board configuration. The component may be surface mounted on the component carrier. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1, FIG. 2, FIG. 3, FIG. 4, FIG. 5, FIG. 6, FIG. 7, FIG. 8, and FIG. 9 illustrate cross-sectional views of structures obtained during carrying out a method of manufacturing a component carrier according to an exemplary embodiment of the disclosure, shown in FIG. 9.

FIG. 3A illustrates a cross-sectional view of a structure obtained during carrying out a method of manufacturing a component carrier according to another exemplary embodiment of the disclosure.

FIG. 10, FIG. 11, FIG. 12, FIG. 13, FIG. 14, FIG. 15, FIG. 16, FIG. 17, FIG. 18, FIG. 19, FIG. 20, FIG. 21, and FIG. 22 illustrate cross-sectional views of structures obtained during carrying out a method of manufacturing a component carrier according to another exemplary embodiment of the disclosure, shown in FIG. 22.

FIG. 23, FIG. 24, FIG. 25, FIG. 26, FIG. 27, and FIG. 28 illustrate cross-sectional views of structures obtained during carrying out a method of manufacturing a component carrier according to another exemplary embodiment of the disclosure, shown in FIG. 28.

FIG. 29 illustrates a component carrier according to still another exemplary embodiment of the disclosure.

FIG. 30 illustrates a component carrier according to yet another exemplary embodiment of the disclosure.

FIG. 31 shows a device for stamping a surface profile in a design layer using a working mold according to an exemplary embodiment.

FIG. 32 illustrates a component carrier according to still another exemplary embodiment of the disclosure.

FIG. 33 illustrates a component carrier according to yet another exemplary embodiment of the disclosure.

FIG. 34 illustrates a component carrier according to yet another exemplary embodiment of the disclosure.

FIG. 35, FIG. 36, and FIG. 37 show three-dimensional views of stamped design layers used for manufacturing component carriers according to exemplary embodiments of the disclosure.

FIG. 38, FIG. 39, FIG. 40, FIG. 41, FIG. 42, FIG. 43, FIG. 44, FIG. 45, FIG. 46, FIG. 47, FIG. 48, and FIG. 49 illustrate cross-sectional views of structures obtained during carrying out a method of manufacturing a component carrier according to another exemplary embodiment of the disclosure, shown in FIG. 49.

FIG. 50 illustrates a component carrier according to yet another exemplary embodiment of the disclosure.

FIG. 51 illustrates a component carrier according to yet another exemplary embodiment of the disclosure.

FIG. 52 illustrates a component carrier according to yet another exemplary embodiment of the disclosure.

### DETAILED DESCRIPTION OF EXEMPLARY EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the disclosure have been developed.

According to an exemplary embodiment of the disclosure, a Nanoimprint Lithography (NIL)-based design layer may be used as a basis for forming a wiring structure for a component carrier such as a printed circuit board. After stamping indentations in the still uncured design layer for defining the wiring structure by a working mold, a seed layer may be formed on the profiled design layer. More precisely, after (or during) stamping, the design layer may be cured and afterwards the seed layer will be formed. For defining regions in which subsequently an electroplating structure may be formed on the seed layer, an electroplating protection structure (such as a resist ink) may be formed and structured on the seed layer so that it remains on non-indented portions of the profiled design layer only while being removed from the indentations of the design layer. In a subsequent electroplating (preferably galvanic plating) process, the indentations may then be filled partially or entirely with electrically conductive material such as copper on exposed seed layer portions, while surface portions being constituted by the patterned protection structure will not be covered by unwanted additional electrically conductive material. Advantageously, a preferably planar structure may then be obtained by merely removing the protection structure. However, a complex CMP (chemical mechanical polishing) process may be dispensable in view of the simple protection structure removal process. Consequently, a simple and precise NIL-based process for producing a component carrier or circuit board is thereby provided which avoids complex manufacturing processes.

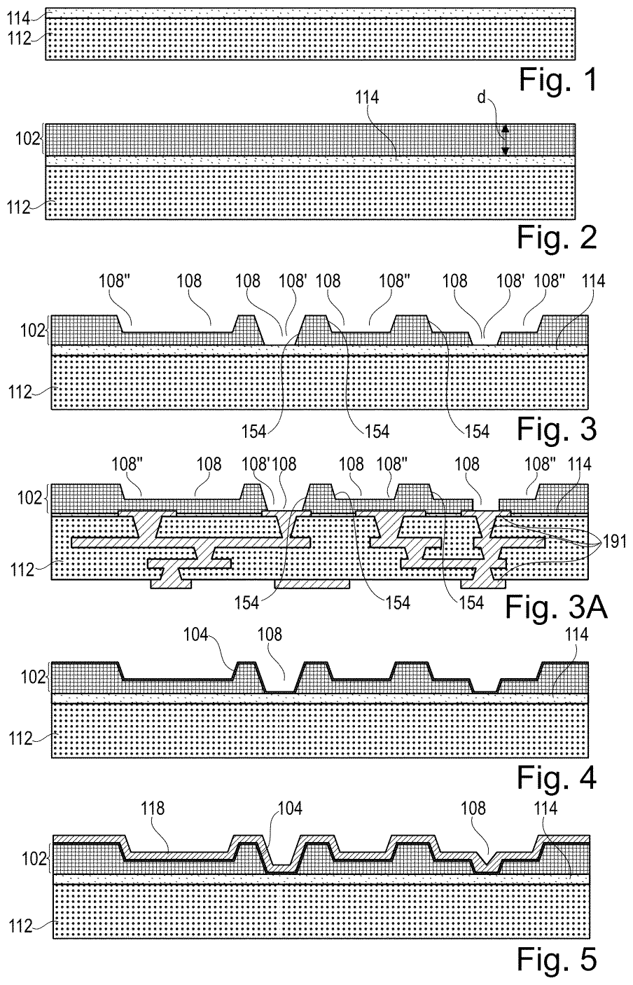

FIG. 1 to FIG. 9 illustrate cross-sectional views of structures obtained during carrying out a method of manufacturing a component carrier 100 according to an exemplary embodiment of the disclosure, shown in FIG. 9.

As shown in FIG. 1, a temporary carrier 112 is provided on which a release layer 114 (which is optional) is formed. For example, the temporary carrier 112 may be a supporting glass plate. The release layer 114 may have poorly adhesive properties and may be formed for example of polytetrafluoroethylene. In particular in an embodiment in which the carrier 112 remains part of the readily manufactured component carrier 100, the release layer 114 may be omitted.

Referring to FIG. 2, a design layer 102 may be formed on the release layer 114 which covers the carrier 112. For example, a thickness d of the design layer 102 may be in a range from 0.1 μm to 25 μm. Hence, this may make it possible to create a very thin build-up. Advantageously, the design layer 102 may be configured as Nanoimprint Lithography (NIL) layer. In other words, the release layer 114 on the carrier 112 may be coated with an NIL imprintable resist. After formation on the release layer 114, the design layer 102 may still be at least partially uncured, i.e. may be in particular still capable of cross-linking or polymerizing.

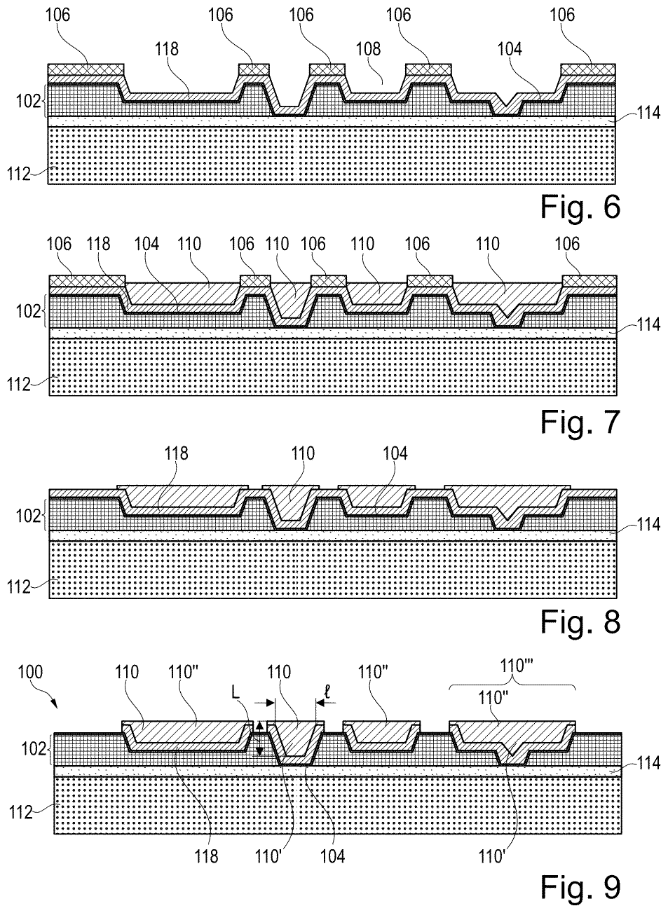

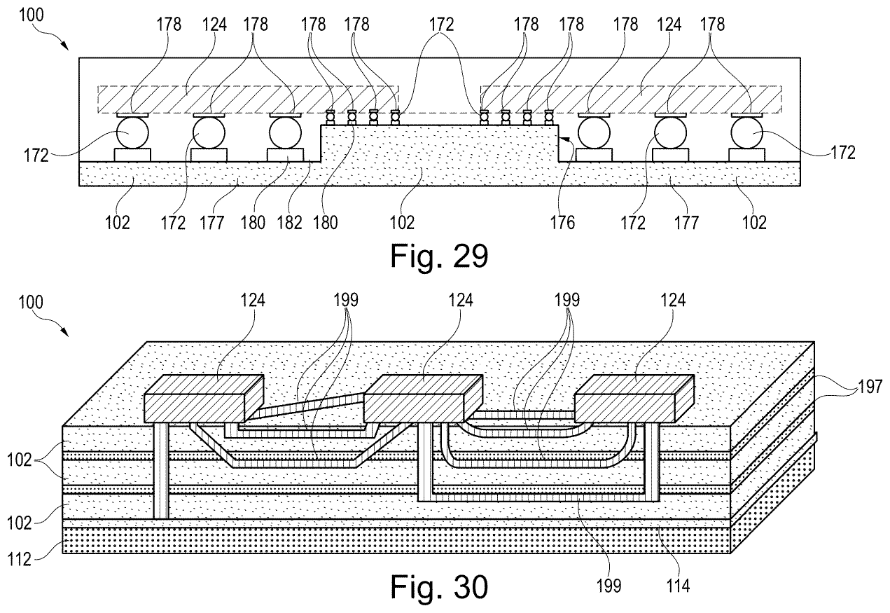

Referring to FIG. 3, a surface profile may be stamped in the design layer 102. For this purpose, a working mold (not shown in FIG. 3, compare FIG. 31) may be pressed into the still deformable design layer 102 so that a surface profile of the working mold is transferred into an inverse surface profile imprinted in the design layer 102. Descriptively speaking, the created surface profile in the design layer 102 corresponds to a wiring pattern to be formed. In the shown embodiment, formation of a surface profile in the design layer 102 may create a plurality of indentations 108. Said indentations 108 may comprise through holes 108′ and/or blind holes 108″. Thus, the stamping forms indentations 108 of different depth and/or different length in the design layer 102. More specifically, the through holes 108′ have a larger depth and a smaller length than the blind holes 108″. In the readily manufactured component carrier 100, the through holes 108′ may form vertical electrically filled vias, whereas the blind holes 108″ may form horizontal electrically conductive traces (which may be denoted as embedded traces).

When there is an embedded trace, a surface finishing may be dispensable (in particular if it is covered by the NIL resist). Hence depending on the application, no solder resist or surface finishing may be needed.

As can be taken from FIG. 3 as well, the formed indentations 108 in the design layer 102 taper inwardly. This is the result of a corresponding tapering shape of protrusions of the working mold creating the indentations 108 in the design layer 102. Forming tapering (rather than vertical) indentations 108 may advantageously suppress issues concerning undesired adhesion between the working mold and the design layer 102. With vertically extending sidewalls, a high friction between working mold and design layer 102 may occur, which may lead to defects and a low imprinting speed. With tapering sidewalls of the working mold and indentations 108 in the design layer 102, a high processing velocity and a low defect rate may be obtained.

Advantageously, the design layer 102 may be cured simultaneously during the process of stamping. For this purpose, the working mold (preferably optically transparent, for instance made of glass, transparent, flexible, cross-linked silicone rubbers, and/or a combination of both) may be provided with a curing UV lamp configured for emitting UV radiation. More specifically, said UV lamp may emit UV radiation during imprinting indentations 108 in the design layer 102. This accelerates the manufacturing process and makes a subsequent curing procedure dispensable. As an alternative to a UV lamp, another optical emitter or a heat source may be used for curing. Such an optical emitter or heat source may be integrally formed together with the working mold or may be provided as a separate member. A device for stamping design layer 102 using a working mold is illustrated in FIG. 31.

Under undesired circumstances it may happen that residues of the design layer 102 remain, after stamping by the working mold, in indentations 108 which shall be processed for creating a respective through hole 108′. Since this undesired phenomenon may be critical for a subsequent manufacturing process, it may be advantageously possible to remove, preferably by plasma etching, residues of the design layer 102 in at least one bottom region of the indentations 108 of the profiled design layer 102.

Referring to reference signs 154 in FIG. 3, the formation of the indentations 108 by stamping using a working mold may also ensure that exposed surface portions of the design layer 102 delimiting indentations 108 have a very low roughness Ra of preferably less than 50 nm. This makes the manufacture of tiny structures possible and may lead to a component carrier 100 having excellent high-frequency properties.

As a side remark and referring to FIG. 3A, carrier 112 may also be a permanent carrier in exemplary embodiments of the disclosure. In particular, instead of a temporary carrier, an already structured component carrier-type carrier 112 (for example an interposer, an IC-substrate, or a PCB) can be used. An electrically conductive wiring 191 may be integrated in such a carrier 112.

In the following, the manufacturing process will be further described based on the structure of FIG. 2. However, a skilled person will understand that a corresponding manufacturing process can be carried out based on the structure of FIG. 3A.

As shown in FIG. 4, a layer of an adhesion promoter 104 may then be applied on the stamped design layer 102. Such an optional but advantageous process may prepare a subsequent formation of an electrically conductive seed layer 118. For example, the adhesion promoter 104 may be made of or may be based on silicon nitride, silicon oxide, and/or silane, or a mixture of these. Additionally or alternatively to the provision of the adhesion promoter 104, it may also be possible to form a barrier layer (not shown) on the stamped design layer 102. Such a barrier layer may be configured for inhibiting oxidation and/or material migration between material below and above the barrier layer. When using sputtering, the process according to FIG. 4 can be skipped.

Referring to FIG. 5, an electrically conductive seed layer 118 (for instance a thin seed layer with a thickness below 5 μm, and in particular below 1 μm) may be formed on the adhesion promoter 104 (and/or on an optional barrier layer) on the stamped design layer 102. For instance, the seed layer 118 may be formed by electroless deposition of chemical metal or by sputtering. Said seed layer 118 may for example be composed of a palladium base layer and a copper layer grown thereon by a chemical process. Alternatively, the seed layer 118 may be a physically deposited, for instance sputtered, titanium and copper layer.

Referring to FIG. 6, an electroplating protection structure 106 may be formed on the surface of the structure shown in FIG. 5. For example, the electroplating protection structure 106 may be a resist ink. The material of the electroplating protection structure 106 may be dielectric and easily removable or strippable and may inhibit deposition of electroplated metal during a subsequent electroplating process. The protection structure 106 may be patterned so as to be formed selectively on portions of the seed layer 118 apart from indentations 108 of the profiled design layer 102. More specifically, the protection structure 106 may remain above non-deformed or non-stamped portions of the design layer 102, whereas the protection structure 106 may be absent or removed in regions of the indentations 108.

Structuring of the protection structure 106 is preferably done by the profiled design layer 102, i.e. by the previous NIL imprinting resulting in different resist heights. The protection structure 106—only of the top NIL resist layer coated with the metal seed layer 118—can be done with any non-selective, flat stamp coated with a thin film of protection ink, for example of a few nanometers to a few micrometers in thickness. The flat, protective ink coated surface will only form contact with the highest surfaces of the profiled design layer 102 (i.e. NIL imprinted structures) on the panel. By taking this measure, it may be possible to make use of the fact that the profiled design layer 102 provides several levels of height by blocking selectively only the top layers.

Alternatively, the patterning of the protection structure 106 may be carried out by a lithography and etching process.

Advantageously, the patterned protection structure 106 may prevent overplating in a subsequent electroplating process and may thus avoid a costly and time-consuming as well as difficult polishing process for removing overplated metal. In particular polishing processes such as CMP (chemical mechanical polishing) are difficult to be executed on panel format, i.e. for formation of PCB-type component carriers in a batch process.

As shown in FIG. 7, an electroplating structure 110 may then be formed by electroplating selectively on portions of the seed layer 118 exposed with respect to the electroplating protection structure 106. Preferably, such an electroplating process can be embodied as galvanic plating. During electroplating, an electric voltage may be applied to the seed layer 118. Consequently, metallic material of the electroplating structure 110 may be deposited only on exposed surface portions of the seed layer 118. Due to the above-described properties, no substantial amount of metal will thus remain on the surface of the dielectric non-adhesive electroplating protection structure 106.

Preferably, the electroplating process may be continued until the indentations 108 are completely filled up with metal, in particular copper. Thus, the electroplating structure 110 may fill up the indentations 108 entirely (or partially, not shown).

Now referring to FIG. 8, the electroplating protection structure 106 may be removed after the electroplating. For example, this can be accomplished by etching, preferably by plasma etching, for example by reactive ion etching (RIE). Consequently, the surface areas of the seed layer 118 which have previously been covered by the electroplating protection structure 106 are now exposed.

In order to obtain the component carrier 100 shown in FIG. 9, the mentioned portions of the seed layer 118 which have been exposed as a result of the removing of the electroplating protection structure 106 may then be removed. For this purpose, a differential etching process may be executed to remove electrically conductive seed material between traces and vias created in the indentations 108. For example, the process of removing exposed portions of the seed layer 118 may be carried out by wet etching. Preferably, such an etching process may be executed with controlled parameters so that a target thickness of only a few micrometers of metallic material is removed from the surface. This avoids excessive removal of metallic material from an interior of the indentations 108.

It is also possible to remove, for instance by etching, portions of the adhesion promoter 104 which are exposed when the previously exposed portions of the seed layer 118 are removed.

As a result, the illustrated component carrier 100 may be obtained. The component carrier 100 comprises the illustrated NIL-type and meanwhile cured design layer 102 in which a surface profile has been stamped. As shown, the electrically conductive seed layer 118 selectively lines the indentations 108 of the stamped design layer 102. Furthermore, the electroplating structure 110 is formed selectively on separated portions of the seed layer 118, but not in between.

Said electroplating structure 110 forms, together with underlying portions of the seed layer 118, electrically conductive sub-structures of different depth and different length in the design layer 102. More specifically, the electroplating structure 110, together with underlying portions of the seed layer 118, form trace-type sub-structures 110″ (corresponding to indentations according to reference sign 108″) and via-type sub-structures 110′ (corresponding to indentations according to reference sign 108′). As shown in FIG. 9, a combined trace-and-via structure 110′″ is obtained which comprises a combined integrally formed trace-type sub-structure 110″ and via-type sub-structure 110′.

As shown in FIG. 9, the electroplating structure 110 may also form a sub-structure having a depth-to-diameter ratio of larger than 1, wherein the depth is indicated with “L” and the diameter is indicated with “I”. Hence, the described manufacturing architecture is in particular compatible with the formation of vertical through connections having an aspect ratio of 1 or even more than 1.

Furthermore, the electroplating structure 110 has tapering sidewalls. This is a fingerprint of the tapering sidewalls of the protrusions of the working mold forming the indentations 108.

Advantageously, a roughness Ra of sidewall surfaces of the profiled design layer 102—and thus a roughness of sidewalls of electrically conductive structures defined by the seed layer 118 and the electroplating structure 110 being delimited by the surface profile formed in the design layer 102—may be not more than 50 nm. Also, this feature is the result of the formation of the indentations 108 by stamping using a working mold and leads to excellent high-frequency properties of the obtained component carrier 100.

Moreover, the illustrated component carrier 100 may be further processed, for instance for creating a further build-up of one or more PCB-type stacks (such as an IC substrate, an interposer or a PCB) of electrically conductive layer structures and/or electrically insulating layer structures on one or both opposing main surfaces of the design layer 102 according to FIG. 9. Such additional layer structures may comprise patterned copper foils, patterned resin sheets comprising optionally reinforcing particles such as glass fibers, copper filled laser vias extending through a respective resin sheet, etc. Descriptively speaking, a PCB-type layer stack may be laminated on top and/or bottom of the processed design layer 102. For example, it is possible to form further layer structures on top and/or bottom of the component carrier 100 shown in FIG. 9. It is also possible to remove the carrier 112 at the release layer 114. A component carrier 100 which is extended by laminating additional layer structures thereon may be denoted as plate-shaped and partially laminate-type component carrier 100 with stamped and metal-filled design layer 102 therein.

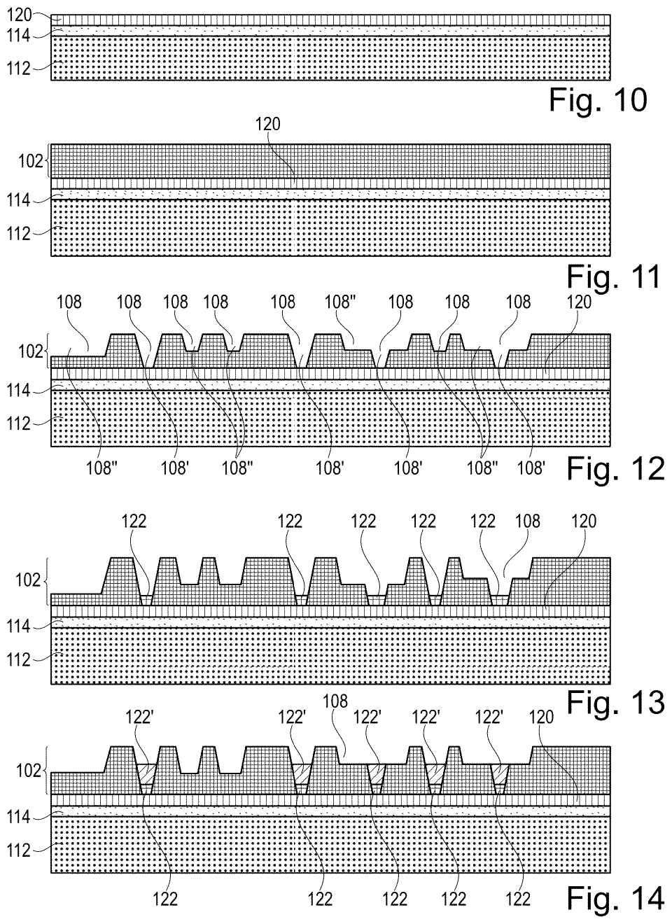

FIG. 10 to FIG. 22 illustrate cross-sectional views of structures obtained during carrying out a method of manufacturing a component carrier 100 according to another exemplary embodiment of the disclosure, shown in FIG. 22.

A starting point of the manufacturing method according to FIG. 10 to FIG. 22 is illustrated in FIG. 10. Based on a release layer 114 (which is optional) on a carrier 112, an electrically conductive layer 120 (such as a sputtered seed layer or an attached copper foil) may be formed.

Referring to FIG. 11, a design layer 102 may be formed on the electrically conductive layer 120. The design layer 102 may be formed and may have the properties as described above referring to FIG. 2.

In order to obtain the structure shown in FIG. 12, the design layer 102 may be stamped on the electrically conductive layer 120 by a profiled working mold (not shown) so that predefined surface portions of the electrically conductive layer 120 are exposed with respect to the stamped design layer 102. Treating the design layer 102 with a working mold may be accomplished as described above referring to FIG. 3. As a result, indentations 108 may be obtained which comprise through holes 108′ (which may later form metal filled vias) and blind holes 108″ (which may later form electrically conductive traces) characterized by different depths and different lengths in the design layer 102, as described above referring to FIG. 3. As described above as well, an etching (preferably plasma etching) process may be carried out optionally to ensure that no residues of the design layer 102 remain at the bottoms of the through holes 108′.

Simultaneously with the profiling, or subsequently, the design layer 102 may be cured by subjecting the deformed design layer 102 to heat or appropriate electromagnetic radiation, such as UV radiation.

Referring to FIG. 13, a first portion of a metallic base structure 122 may be formed selectively on the exposed surface portions of the electrically conductive layer 120 and in the corresponding through hole-type indentations 108 of the profiled design layer 102 by electroplating. The first portion of the metallic base structure 122 may comprise for example nickel and optionally a further metal to properly define the functional properties of the metallic filling of the through hole-type indentations 108 shown in FIG. 12 with reference sign 108′. In a preferred embodiment, the first portion of the metallic base structure 122 is a solderable material such as tin. After removing the carrier 112 for exposing the first portion of the metallic base structure 122, such a preferred embodiment has the advantage that the exposed and preferably protruding solderable first portion of the metallic base structure 122 may function as a solder cap or tip for creating a solder connection (for instance in a way described below referring to FIG. 47 to FIG. 49). No metal will be deposited during electroplating in the blind hole-type indentations 108 shown in FIG. 12 with reference signs 108″ due to the closed dielectric bottom of the design layer 102. Preferably, the first portion of the metallic base structure 122 illustrated in FIG. 13 may be formed by electroplating, in particular by galvanic plating, and will thus be created on exposed surface portions of the electrically conductive layer 120 only.

As shown in FIG. 14, it may be subsequently possible to form a second portion of the metallic base structure 122′ on the first portion of the metallic base structure 122. For this purpose, a further electroplating stage may be executed. For instance, the shown second portion of the metallic base structure 122′ may be made of copper (or more generally of the same or another metal than the first portion of the metallic base structure 122).

Referring to FIG. 15, an electrically conductive seed layer 118 (for instance a thin seed layer with a thickness below 5 μm, and in particular below 1 μm) may be formed on the entire upper main surface of the structure shown in FIG. 14. More specifically, the seed layer 118 may be formed on exposed surface portions of the profiled design layer 102, as well as on exposed surface portions of the second portion of the metallic base structure 122′.

Referring to FIG. 16, a dielectric and poorly adhesive electroplating protection structure 106 may then be formed on the surface of the structure shown in FIG. 15. The protection structure 106 may be patterned so as to remain selectively on portions of the seed layer 118 apart from indentations 108 of the profiled design layer 102. Said indentations 108 are partially filled by the first and second portions of the metallic base structure 122, 122′ and with a corresponding portion of the seed layer 118 or are partially filled by material of the seed layer 118 only. This structuring of the protection structure 106 may be carried out by a lithography and etching process. As explained above, the patterned protection structure 106 may advantageously avoid undesired overplating in a subsequent electroplating process and may render a complex and costly CMP process dispensable.

Referring to FIG. 17, a further electroplating (in particular galvanic) process is executed for selectively electroplating additional metallic material in the only partially metallized indentations 108 to fill them up preferably completely with metallic medium. Thus, an electroplating structure 110 may be formed on the portions of the seed layer 118 covering the metallic base structure 122, 122′. Furthermore, the electroplating structure 110 may be formed also on the exposed portions of the seed layer 118 formed in the indentations 108 directly on the design layer 102. For example, the electroplating structure 110 may comprise copper (or more generally the same metal as or another metal than the first and/or the second portions of the metallic base structure 122, 122′).

It should be mentioned that a person skilled in the art is aware of the fact that, in a cross-sectional view of the structure shown in FIG. 17, it is possible to visually distinguish each of the first portion of the metallic base structure 122, the second portion of the metallic base structure 122′, the seed layer 118, and the electroplating structure 110.

Referring to FIG. 18, the electroplating protection structure 106 may then be removed after the electroplating. For example, this can be accomplished by etching, preferably by plasma etching, for example by reactive ion etching (RIE). Consequently, the surface areas of the seed layer 118 which have previously been covered by the electroplating protection structure 106 are now exposed. Thereafter, said exposed surface portions of the seed layer 118 may be removed for separating wiring structures formed in the indentations 108.

In an embodiment, the electroplating structure 110 may protrude beyond the design layer 102. More specifically, the NIL-pattern may protrude from the NIL-resist.

The electrically conductive wiring structures obtained as a result of the described manufacturing process are shown in a detail 158, in a detail 160 and in a detail 162 of FIG. 18, respectively.

As illustrated in detail 158, through hole-type wiring structures 164 extending completely through profiled design layer 102 have tapering sidewalls. A bottom portion of a respective wiring structure 164 is constituted by bottom-sided portion of the metal base structure 122, wherein a top-sided portion of the metal base structure 122′ is formed directly on the bottom-sided portion 122. A remaining volume of the wiring structure 164 is lined with seed layer 118 covering a top surface of the metal base structure 122, 122′ as well as an exposed sidewall of the design layer 102. A remaining volume of the wiring structure 164 delimited by the seed layer 118 is filled with the electroplating structure 110.

As illustrated in detail 160, blind hole-type wiring structures 166 extending only partially through profiled design layer 102 have tapering sidewalls and a horizontal bottom surface. Both the latter mentioned tapering sidewalls as well as the horizontal bottom surface are lined with seed layer 118. A remaining volume of the wiring structure 166 delimited by the seed layer 118 is filled with the electroplating structure 110.

As illustrated in detail 162, through hole-type wiring structures 168 extending completely through profiled design layer 102 have tapering sidewalls with a stepped profile, a corresponding step being indicated by reference sign 170. Wiring structures 168 correspond to wiring structures 164 with the difference that the wiring structures 168 have step 170 between portions of the tapering sidewalls and therefore form a hybrid of a via-type wiring structure in a bottom portion and a trace-type wiring structure in a top portion.

As shown, fully embedded electrically conductive structures can be obtained, both of a via-type (see wiring structures 164) and of a trace-type (compare wiring structures 166), as well as a combination of both (compare wiring structures 168).

The structure shown in FIG. 18 can be used as a readily manufactured component carrier 100.

Highly advantageously, the indentations 108 can be filled with two or more different metallic substructures (see reference signs 122, 122′, 118, 110) which may be made of two or more different metallic materials for fine-tuning the properties of the wiring structures 164, 166, 168. Alternatively, an entire wiring structure 164, 166, 168 may be filled with a single metallic material only, for example copper, with material interfaces in between.

In the following, it will be described how, based on the structure shown in FIG. 18, a further build-up of the obtained component carrier 100 may be created.

Referring to FIG. 19, a further build-up 116 of the component carrier 100 is formed on the profiled design layer 102 with sections of the seed layer 118, with the metallic base structure 122, 122′ and with the electroplating structure 110. For this purpose, a further design layer 102′ is provided in which a further surface profile is stamped, a further metallic base structure is formed, a further electrically conductive seed layer is provided for selectively lining further indentations of the stamped further design layer 102′, and a further electroplating structure is formed selectively on or above separated portions of the further seed layer. In other words, the further design layer 102′ may be processed correspondingly as the design layer 102, for example as described referring to FIG. 10 to FIG. 18. Correspondingly, one or more wiring structures 164′ (which may be designed as wiring structures 164), one or more wiring structures 166′ (which may be designed as wiring structures 166), and/or one or more wiring structures 168′ (which may be designed as wiring structures 168) may be formed in further design layer 102′, as described above for design layer 102. Moreover, the further design layer 102′ (with one or more wiring structures 164′, 166′ and/or 168′) may be stacked on the design layer 102 (with one or more wiring structures 164, 166 and/or 168). Highly advantageously, stacking of the design layers 102, 102′ may be accomplished so that the wiring structures 164′, 166′ and/or 168′ on the one hand and the wiring structures 164, 166 and/or 168 on the other hand are electrically connected with each other in a landless way, i.e. without connection pads. Also, the structure shown in FIG. 19 may be used as readily manufactured component carrier 100. Descriptively speaking, the plurality of stacked design layers 102, 102′ filled with wiring structures form a multi-layer redistribution structure.

Referring to FIG. 20, a component 124 is surface mounted on the stacked design layers 102, 102′ and can be electrically connected to any of the wiring structures 164′, 166′, 168′, 164, 166, 168, for example by soldering or other appropriate methods like thermal compression bonding. Soldering may be accompanied by solder structures 172 arranged between the stacked design layers 102, 102′ on the one hand and the component 124 on the other hand. For example, component 124 may be a semiconductor die.

As shown in FIG. 21, the component 124 being surface mounted on and being electrically coupled with the stacked design layers 102, 102′ may then be overmolded by a mold compound 174.

Referring to FIG. 22, it is then possible to detach the stacked design layers 102, 102′ with the integrated wiring structures 164, 166, 168, 164′, 166′, 168′ and with the surface mounted and overmolded component 124 from the carrier 112 at the release layer 114. By taking this measure, the wiring structures 164, 166, 168 may be exposed so as to be connectable to an electronic periphery (not shown).

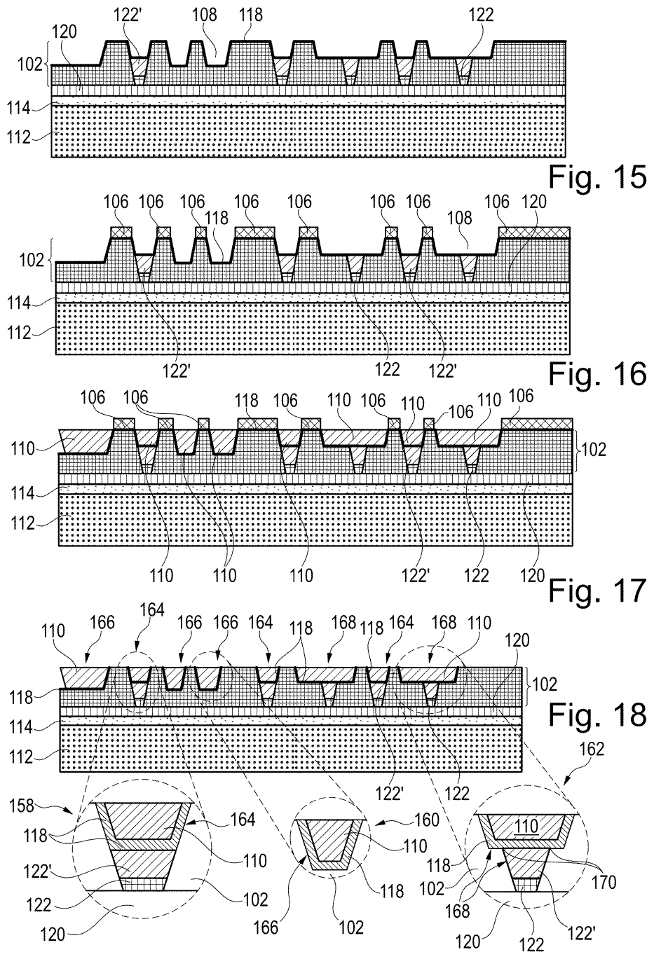

FIG. 23 to FIG. 28 illustrate cross-sectional views of structures obtained during carrying out a method of manufacturing a component carrier 100 according to another exemplary embodiment of the disclosure, shown in FIG. 28.

Referring to FIG. 23, design layers 102, 102′ with integrated wiring structures 164, 166, 168 and 166′, 168′, respectively, are stacked on an electrically conductive layer 120 being arranged, in turn, on a release layer 114 attached to a carrier 112. Thus, FIG. 23 illustrates that exemplary embodiments of the disclosure enable a multi-layer and any layer stack-up with permanent NIL resist. Advantageously, a plate-to-plate NIL imprinting may be possible with an alignment accuracy of at least 2 μm. Furthermore, electrically connecting wiring structures 164, 166, 168 and 166′, 168′ of connected design layers 102, 102′ may be accomplished by landless vias (which may be advantageous in particular for high-frequency applications). Moreover, a line space ratio L/S below 5 μm/5 μm may be possible when creating the illustrated embedded traces.

Referring to FIG. 24, carrier 112 may be detached at release layer 114, and the panel may be rotated by 180°, i.e. may be turned upside down.

As shown in FIG. 25, the release layer 114 may be removed.

If desired or required, the electrically conductive layer 120 (which may be a copper seed layer) may be etched. In order to obtain the structure shown in FIG. 26, a plasma back etching of copper structures is completed.

Referring to FIG. 27, components 124 are assembled by surface mounting. Mechanical and electrical connection of the components 124 to wiring structures 164, 166, 168 of the design layer 102 may be accomplished by soldering, or by thermal compression bonding. As shown, each of the components 124 may be mounted on the design layer 102 by solder structures 172 arranged between the component 124 and the design layer 102.

In order to obtain the component carrier 100 according to FIG. 28, the surface mounted components 124 may be overmolded by a mold compound 174.

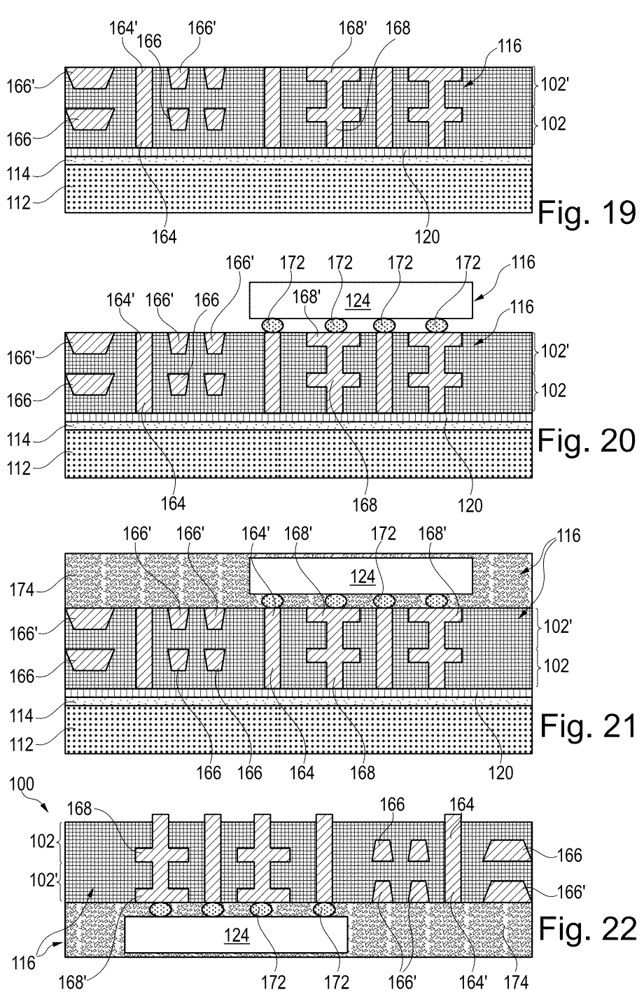

FIG. 29 illustrates a component carrier 100 according to still another exemplary embodiment of the disclosure. According to FIG. 29, two surface mounted components 124 (for example semiconductor chips) are arranged side-by-side on the design layer 102 and are electrically coupled with each other by electrically conductive connection structures 180 at a protrusion 176 of the design layer 102 and on the design layer 102 apart from the protrusion 176.

According to FIG. 29, the design layer 102 is also used for horizontally connecting the laterally juxtaposed components 124 which are surface mounted on the design layer 102 at the same vertical level. To accomplish this connection, the design layer 102 is equipped with central protrusion 176 protruding vertically beyond horizontal surface portions 177 of the stepped design layer 102. Bottom-sided pads 178 of the two components 124 are electrically connected with each other and with wiring structures of the design layer 102 by electrically conductive connection structures 180 on the protrusion 176 of design layer 102 and on design layer 102 apart from the protrusion 176. By the illustrated connection architecture, a conventionally used silicon bridge may become dispensable.

According to FIG. 29, each of the two components 124 comprises pads 178 having different pitch sizes (in particular having different diameters) and being electrically coupled with the electrically conductive connection structures 180 having different pitch sizes (in particular having different diameters) by connection structures which are here embodied as solder structures 172 having different dimensions. As shown, each of the components 124 may have pads 178 with different pitch sizes, i.e. a first group of pads 178 having a smaller diameter than a second group of pads 178. Larger pads 178 of a respective component 124 are coupled with larger connection structures 180 of the design layer 102 by larger solder structures 172, whereas smaller pads 178 of said component 124 are coupled with smaller connection structures 180 of the design layer 102 by smaller solder structures 172. With an NIL-based design layer 102, it is not only possible to realize pads 178 for those different sizes, but it may also be possible to create different heights, so that the areas having a larger pitch size (and thus are connected with larger solder balls) are on another vertical level than the tighter connection pads 178, i.e. having a smaller pitch size (and thus being connected by smaller solder balls).

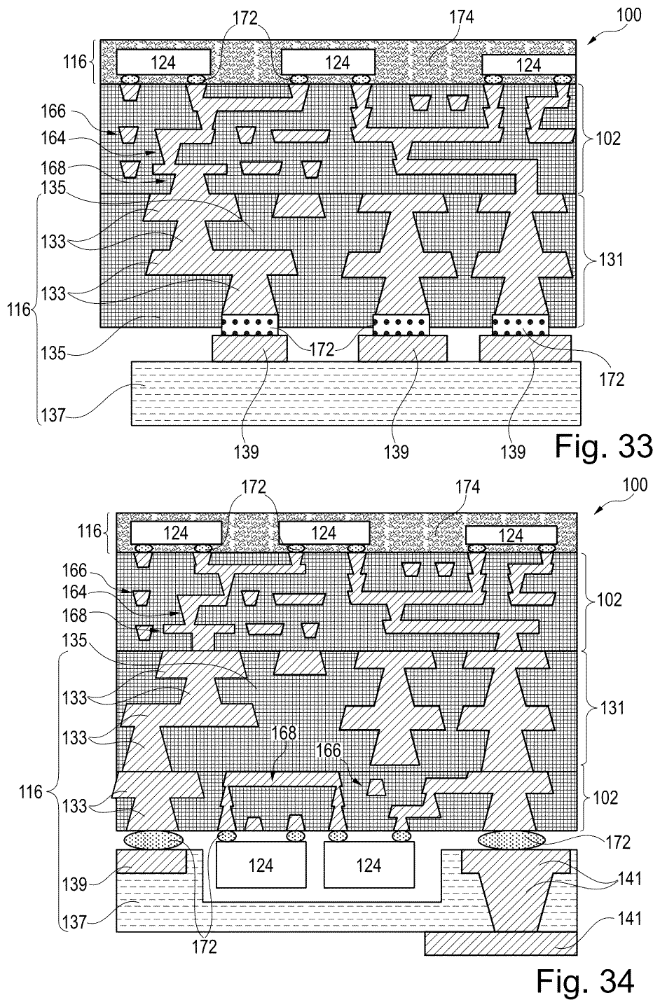

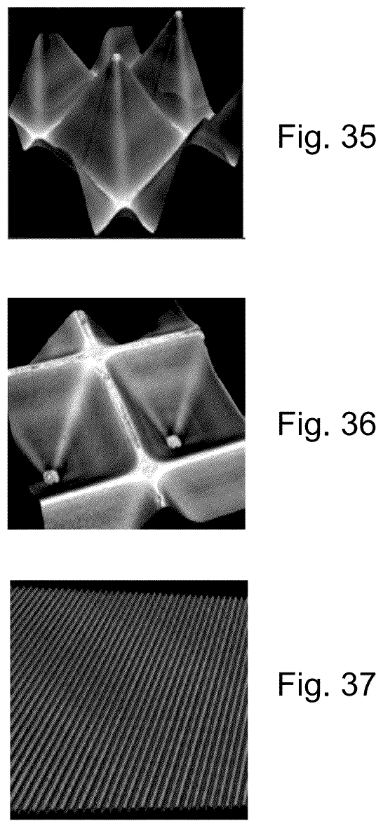

In a further embodiment (not shown), at least one first pad of the pads 178 has a smaller pitch size than at least one second pad of the pads 178 having a larger pitch size, wherein the at least one first pad is electrically coupled with at least one first of the electrically conductive connection structures 180 on the design layer 102, and wherein the at least one second pad is electrically coupled with at least one second of the electrically conductive connection structures 180 on a laminated printed circuit board layer stack 131 (see FIG. 33 or FIG. 34) apart from the design layer 102. Hence, only the area with tight connection pads 178 may be realized with a design layer 102 formed in NIL-technology, for example directly on a component carrier 100, or as a separate board which is then mounted on the component carrier 100.

It is also possible to form a wiring structure 182 which extends partially horizontally and partially vertically between the electrically conductive connection structures 180 on the protrusion 176 and apart from the protrusion 176 on the design layer 102.

The embodiment of FIG. 29 shows that the NIL-type design layer 102 may also function as a bridge or redistribution structure for one or more surface mounted components 124 of the component carrier 100. Hence, a NIL-type design layer 102 may also be configured for a fan-out function in a component carrier 100.

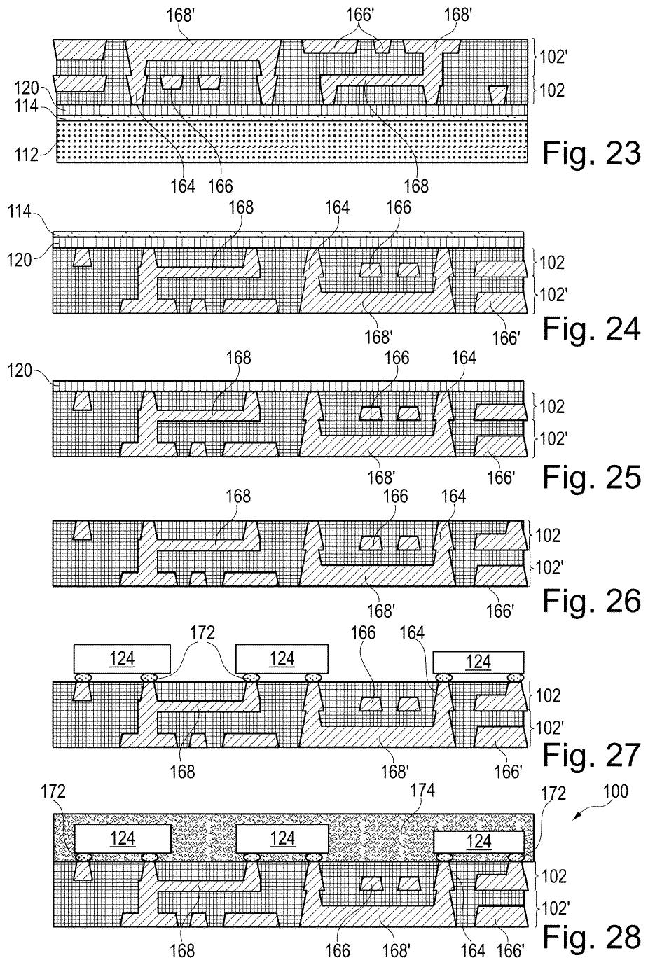

FIG. 30 illustrates a component carrier 100 according to yet another exemplary embodiment of the disclosure.

According to FIG. 30, the electroplating structure 110 comprises three-dimensionally curved substructures indicated by reference sign 199. Such substructures may be formed, for instance also with undercut or the like, by the above-described principles for forming wiring structures 164, 166, 168 and by the combination of multiple stacked design layers 102. Optionally, adjacent design layers 102 may be mutually connected by optional connection layers 197.

For instance, the shown embodiment can be implemented in terms of a chip last 3D manufacturing architecture. With three-dimensionally stamped NIL design layers 102, any slope required for any structure may be designed. Advantageously, stamping may lead to very smooth surfaces with a roughness Ra of less than 100 nm, or even of not more than 50 nm. Plated copper structures may be formed with high crystallinity and substantially without porosity.

In embodiments, one or more NIL-type design layers 102 may be further treated by three-dimensional printing. This may further extend the opportunities of NIL technology for manufacturing component carriers 100, such as printed circuit boards.

FIG. 31 shows a device 150 for stamping a surface profile in a design layer 102 using a working mold 152 according to an exemplary embodiment.

As shown, a planar uncured design layer 102 may be formed on a carrier 112 which may be transported along a support 186. Material of the design layer 102 may be applied to the carrier 112 from a reservoir 188. The working mold 152 may have a designable and preferably tapering surface profile 190 and may stamp an inverse and preferably tapering surface profile 192 in the design layer 102. For this purpose, the working mold 152 may for example rotate using rotating wheels 194 to thereby produce a continuous sheet with a stamped profiled design layer 102. By a light source 196 (such as a UV lamp), the design layer 102 may be cured during stamping.

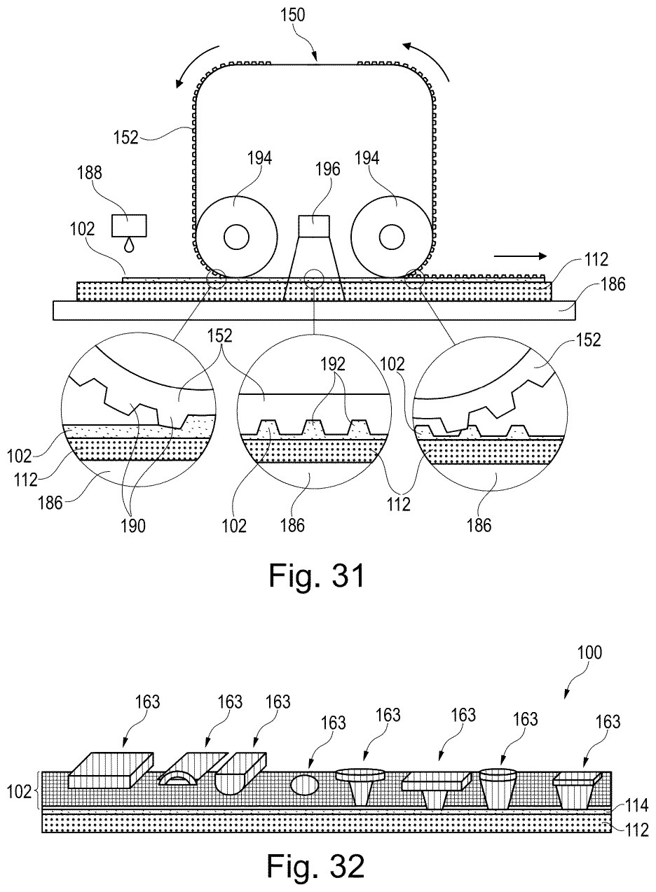

FIG. 32 illustrates a component carrier 100 according to still another exemplary embodiment of the disclosure.

In this embodiment, it is shown that a component carrier 100 with metal plated indentations 108 of one or more profiled design layers 102 can comprise straight or curved traces 163 of very different geometries. The illustrated possible shapes of the traces 163 are (from left to right) a cuboid shape, a convex or concave shape, a half cylindrical shape, a spherical shape, a T-shape (shown with two different aspect ratios), a combined cylindrical and frustoconical shape, and a combined rectangle and frustum shape. Creation of a huge plurality of other shapes is possible, in particular when a plurality of design layers 102 are stacked.

FIG. 33 illustrates a component carrier 100 according to yet another exemplary embodiment of the disclosure. In the shown embodiment, two build-ups 116 on both opposing main surfaces of stacked profiled design layers 102 with integrated wiring structures (for example 164, 166, 168) are illustrated.

On a top side of said design layers 102, a first build-up 116 is formed which is composed of components 124 being surface mounted and electrically connected to the stacked profiled design layers 102 by solder structures 172 and being encapsulated in a mold compound 174.

On a bottom side of said design layers 102, a second build-up 116 is formed which comprises a laminated printed circuit board layer stack 131 (which can be, for example, a PCB, an IC substrate or an interposer). The illustrated laminated printed circuit board layer stack 131 may be composed of electrically conductive layer structures 133 and electrically insulating layer structures 135. For instance, the electrically insulating layer structures 135 may be parallel dielectric layers. For example, the electrically conductive layer structures 133 may comprise patterned copper foils (i.e. patterned metallic layers) and vertical through-connections, for example copper filled laser vias. The electrically insulating layer structures 135 may comprise a resin (such as epoxy resin), optionally comprising reinforcing particles therein (for instance glass fibers or glass spheres). For example, the electrically insulating layer structures 135 may be made of prepreg or FR4. The layer structures 133, 135 may be connected by lamination, i.e. the application of pressure and/or heat.

As shown, the integration density of wiring structures in said design layers 102 may be larger than in said laminated printed circuit board layer stack 131.

On a bottom side of the laminated printed circuit board layer stack 131, a mounting base 137 (such as a motherboard) with electrically conductive connection pads 139 may be connected mechanically and electrically by solder structures 172.

Hence, FIG. 33 illustrates a hybrid package showing a PCB build-up (see reference sign 131) with NIL-layers (see reference sign 102) on one side. Components 124 may be provided on top and optionally also on bottom, together with solder structures 172 (for example solder balls) for mounting.

The metallized design layers 102 form an advanced polymer substrate comprising three fan-out redistribution layers with smaller line space ratio L/S (for instance in a range from 0.5 to 5 μm/0.5 to 5 μm) on top. A larger line space ratio L/S (for instance in a range from 2 to 40 μm/2 to 40 μm, or even larger) may be provided for the substrate in form of laminated printed circuit board layer stack 131 below.

For example, the solder structures 172 may be embodied as solder balls or galvanic plated solder pillars (for instance with the composition of 66 weight % Cu, 33 weight % Sn, and less than 3 weight % Ag).

FIG. 34 illustrates a component carrier 100 according to yet another exemplary embodiment of the disclosure. Also, in the embodiment of FIG. 34, two build-ups 116 are provided on both opposing main surfaces of upper stacked profiled design layers 102 with integrated wiring structures (for example 164, 166, 168) are illustrated.

On a top side of said upper design layers 102, a first build-up 116 is formed which may be embodied as in FIG. 33.

On a bottom side of said upper design layers 102, a second build-up 116 is formed which comprises a laminated printed circuit board layer stack 131, similar as in FIG. 33.

On a bottom side of the laminated printed circuit board layer stack 131, lower design layers 102 are arranged.

On a bottom side of the lower design layers 102, a mounting base 137 (such as a motherboard) with one or more electrically conductive connection pads 139 may be connected mechanically and electrically by solder structures 172. Furthermore, additional components 124 may be surface mounted on a lower side of the lower design layers 102, for instance by solder structures 172. Additional electrically conductive layer structures 141 may be integrated in the mounting base 137. The solder structures 172 of FIG. 34 may be embodied as in FIG. 33.

As shown, the integration density of wiring structures in each of said upper and lower design layers 102 may be larger than in said laminated printed circuit board layer stack 131.

Hence, FIG. 34 illustrates a hybrid package showing a PCB-type stack (see reference sign 131) with areas of NIL-layers (see reference signs 102) between which the PCB-type stack is arranged.

The upper metallized design layers 102 may form an advanced polymer substrate comprising three fan-out redistribution layers with smaller line space ratio L/S (for instance in a range from 0.5 to 5 μm/0.5 to 5 μm, or from 0.5 to 8 μm/0.5 to 8 μm) on top. A larger line space ratio L/S (for instance in a range from 5 to 15 μm/5 to 15 μm, or from 8 to 20 μm/8 to 20 μm) may be provided for the substrate in form of laminated printed circuit board layer stack 131 below.

The electrically conductive layer structures 141 of the mounting base 137 may have a line space ratio L/S (for instance in a range from 50 to 200 μm/50 to 200 μm, or even larger) being larger than the line space ratio L/S of the laminated printed circuit board plastic 131.

The lower metallized design layers 102 may have a line space ratio L/S for instance in a range from 0.5 to 5 μm/0.5 to 5 μm, or from 0.5 to 8 μm/0.5 to 8 μm.

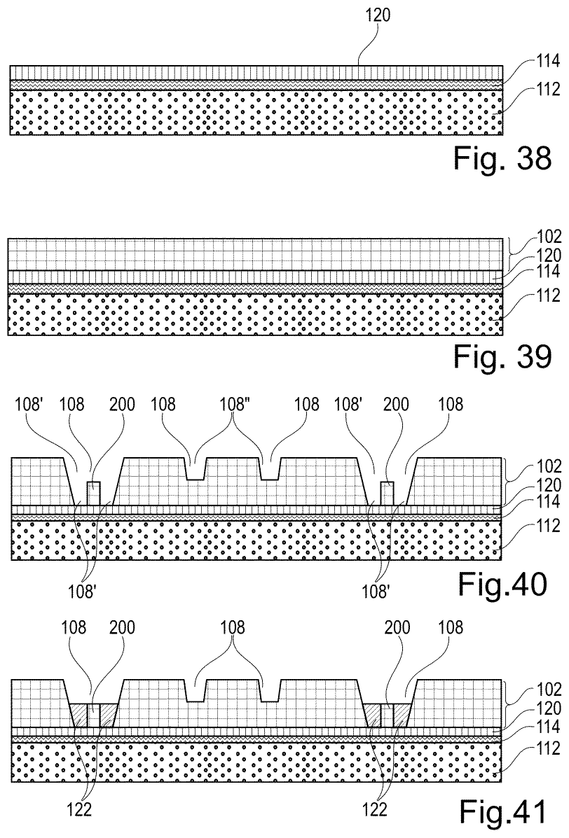

FIG. 35, FIG. 36, and FIG. 37 show three-dimensional views of stamped design layers used for manufacturing component carriers according to exemplary embodiments of the disclosure. Hence, FIG. 35 to FIG. 37 show samples of a NIL-process on panel level and illustrate the topography of the NIL-resist after stamping. While FIG. 35 and FIG. 36 refer to a height of 50 μm and a width of 150 μm, FIG. 37 relates to a height of 230 nm and a width of 400 nm.

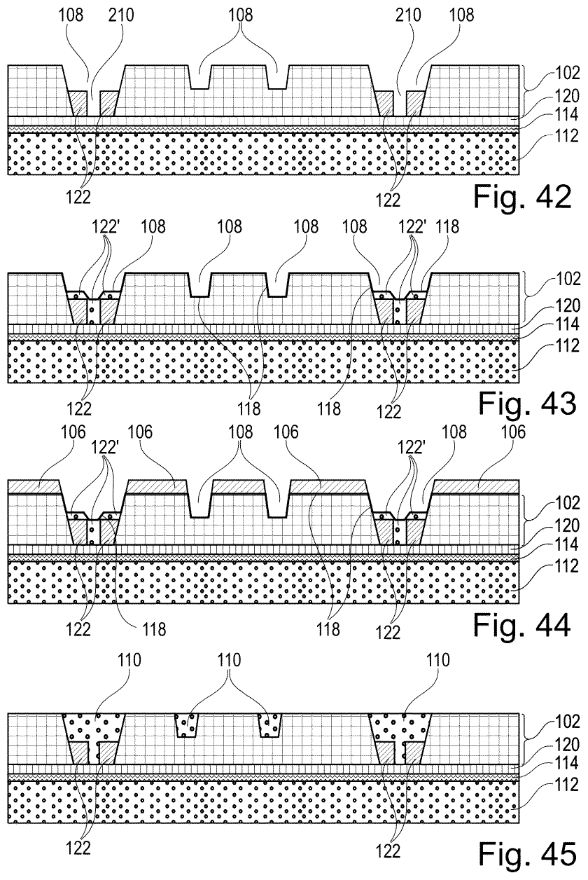

FIG. 38 to FIG. 49 illustrate cross-sectional views of structures obtained during carrying out a method of manufacturing a component carrier 100 according to another exemplary embodiment of the disclosure, shown in FIG. 49.

A starting point of the manufacturing method according to FIG. 38 to FIG. 49 is illustrated in FIG. 38. Based on a release layer 114 (which is optional) on a carrier 112, an electrically conductive layer 120 (such as a sputtered seed layer or an attached copper foil) may be formed. Hence, FIG. 38 may be obtained by coating carrier 112 with release layer 114 and a metallic copper layer as electrically conductive layer 120.

Referring to FIG. 39, a design layer 102 may be formed on the electrically conductive layer 120. The design layer 102 may be formed and may have the properties as described above referring to FIG. 2. More specifically, electrically conductive layer 120 may be coated with an NIL resist layer constituting design layer 102.

In order to obtain the structure shown in FIG. 40, the design layer 102 may be stamped on the electrically conductive layer 120 by a profiled working mold (not shown) so that predefined surface portions of the electrically conductive layer 120 are exposed with respect to the stamped design layer 102. Treating the design layer 102 with a working mold may be accomplished in a similar way as described above referring to FIG. 3. As a result, indentations 108 may be obtained which comprise through holes 108′ (which may later form metal filled vias with solder capability) and blind holes 108″ (which may later form part of a redistribution structure or traces) characterized by different depths and different lengths in the design layer 102, as described above referring to FIG. 3. As described above as well, an etching (preferably plasma etching) process may be carried out optionally to ensure that no residues of the design layer 102 remain at the bottoms of the through holes 108′. In FIG. 40, the through holes 108′ have a frustoconical shape with a bottom-sided pin 200 of design layer material. This approach is of utmost advantage when combined copper-tin-caps shall be formed in a bottom portion of the through holes 108′ to enable a direct solder connection of a metallic filling of the through holes 108′ with low ohmic properties (as described in further detail below). Thus, to obtain the structure shown in FIG. 40, the NIL resist-type design layer 102 is structured by an NIL imprint process for the simultaneous generation of caps (see reference sign 108′) and traces (see reference sign 108″).

Referring to FIG. 41, a first portion of a metallic base structure 122 is formed on a bottom surface in the through holes 108′ of the profiled design layer 102. Advantageously, said first portion of the metallic base structure 122 may be made of a solderable metallic material (i.e. a solder) such as tin. Said solderable metallic material may be formed by plating, in particular electroplating where the electrically conductive layer 120 is exposed by the through holes 108′. Although not shown, said solderable metallic material may also be formed by electroless deposition such as sputtering or by a chemical process, when no electrically conductive layer 120 is present at the bottom of the through holes 108′.

Referring to FIG. 42, the bottom-sided pin 200 of said design layer material in the through holes 108′ may be removed, for instance by etching. Consequently, voids 210 are created at a bottom of the through holes 108′, wherein said voids 210 are surrounded by said first portion of the metallic base structure 122 made of a solderable metallic material. To put it shortly, the resist material of the design layer 102 inside of the caps may be removed by etching.

Referring to FIG. 43, a second portion of the metallic base structure 122′ is formed directly on the first portion of the metallic base structure 122 and on an exposed portion of the electrically conductive layer 120 by electroplating. Hence, said second portion of the metallic base structure 122′ partially covers the electrically conductive layer 120 and partially covers the first portion of the metallic base structure 122. Preferably, said second portion of the metallic base structure 122′ may be made of copper having a very high value of the electrically conductivity. This provides low losses during operation of the readily manufactured component carrier 100. Hence, the metallic base structure 122, 122′ is formed partially from the solderable metallic material and partially from a metal, in particular copper, with a higher electric conductivity than the solderable metallic material. As shown, the solderable metallic material (see reference sign 122) and the metal (see reference sign 122′) with the higher electric conductivity are both formed on a bottom surface of the corresponding through hole-type indentation 108 of the profiled design layer 102 so that the solderable metallic material laterally surrounds the metal with the higher electric conductivity. Descriptively speaking, galvanic copper plating may be carried out to form copper-tin-caps.

Thereafter, an electrically conductive seed layer 118 may be formed on the stamped design layer 102 and on the second portion of the metallic base structure 122′. For instance, the seed layer 118 may be formed by electroless deposition of chemical metal or by sputtering. Said seed layer 118 may for example be composed of a palladium base layer and a copper layer grown thereon by a chemical process. Alternatively, the seed layer 118 may be a physically deposited, for instance sputtered, titanium and copper layer.

Referring to FIG. 44, an electroplating protection structure 106 may be formed, as a temporary resist coating, on the surface of the structure shown in FIG. 43. The material of the electroplating protection structure 106 may be dielectric and easily removable or strippable and may inhibit deposition of electroplated metal during a subsequent electroplating process. The protection structure 106 may be patterned so as to be formed selectively on portions of the seed layer 118 apart from indentations 108 of the profiled design layer 102. More specifically, the protection structure 106 may remain above non-deformed or non-stamped portions of the design layer 102, whereas the protection structure 106 may be absent or removed in regions of the indentations 108.

As shown in FIG. 45, an electroplating structure 110 may then be formed by electroplating selectively on portions of the seed layer 118 exposed with respect to the electroplating protection structure 106. Preferably, such an electroplating process can be embodied as galvanic plating. During electroplating, an electric voltage may be applied to the seed layer 118. Consequently, metallic material of the electroplating structure 110 may be deposited only on exposed surface portions of the seed layer 118. Thus, galvanic copper plating may be carried out in the via-type and trace-type indentations 108. Thereafter, the electroplating protection structure 106 may be removed, for instance by temporary resist stripping.

For the sake of simplicity, the seed layer 118 shown in FIG. 43 and FIG. 44 is not illustrated (although still being present) in FIG. 45 and the subsequent figures.

As shown in FIG. 46, one or more further design layers 102′ may be formed on top of the design layer 102 shown in FIG. 45. In each further design layer 102′, a further electrically conductive filling 202 may be created. In a similar way as shown in FIG. 41 to FIG. 45, said further electrically conductive filling 202 may comprise a metallic base structure, a seed layer and/or an electroplating structure (not shown separately for the further design layer 102′ in FIG. 46). In the shown example, the metallic base structure 122, 122′, the seed layer 118 and the electroplating structure 110 in the design layer 102 may be electrically coupled with and stacked with the further electrically conductive filling 202 in the further design layers 102′. This may create a stacked via configuration. To sum it up, FIG. 46 shows an optional build-up of additional layers via NIL imprinting and copper plating.

Referring to optional FIG. 47, an electronic component 124 (such as a semiconductor chip) being encapsulated in a mold compound 174 may be connected electrically and mechanically by solder balls 172 with exposed upper surfaces of the uppermost electrically conductive filling 202. Thus, chip mounting can be executed, for instance using an optional mold compound 174.

Although not shown, it is also possible to form, on the structure shown in FIG. 46, a build-up of further electrically conductive layer structure(s) (for instance made of copper) and/or electrically insulating layer structure(s) (for instance on the basis of prepreg). Further alternatively, it is possible to mount a laminated layer stack (for example a PCB or an IC substrate) on top of the structure of FIG. 46.

Referring to FIG. 48, the stack composed of the profiled design layers 102, 102′ with the metallic base structure 122, 122′, with the seed layer 118 and with the electroplating structure 110 as well as with the electrically conductive filling 202 is detached from carrier 112 (for instance making use of the optional release layer 114) to thereby expose the solderable metallic material and the metal with the higher electric conductivity. In other words, the metallic base structure 122, 122′ may be exposed. Furthermore, one or more low ohmic solderable protrusions 212 may be formed based on the exposed metallic base structures 122, 122′ by removing a part of the material of the design layer 102.

More specifically, to obtain the structure shown in FIG. 48, the panel may be rotated and the carrier 112 may be detached. Then, the release layer 114 may be removed. Furthermore, the electrically conductive layer 120 may be removed by etching. By a plasma back etching of exposed NIL resist of design layer 102, tin-copper-caps may be created to form the low ohmic solderable protrusions 212. This prepares the structure shown in FIG. 48 perfectly for subsequent low-ohmic soldering.

Just for the sake of clarity, it should be mentioned that the process described referring to FIG. 48 can be executed as well without the processes of FIG. 46 and FIG. 47, for instance directly based on the structure shown in FIG. 45.

Now referring to FIG. 49, the structure shown in FIG. 48 may then be used as a basis for creating a solder connection between the exposed solderable metallic material of the low ohmic solderable protrusions 212 on the one hand and any desired connection body on the other hand. In the illustrated example, said connection body may be an electronic component 124, for instance a bare die or an encapsulated die. Alternatively, such a connection body may also be a mounting base 137, for instance a printed circuit board or an IC substrate. The solderable (for example tin) material of the low ohmic solderable protrusions 212 creates the solder connection, whereas simultaneously the metal with higher electric conductivity (preferably copper) of the low ohmic solderable protrusions 212 ensures a low ohmic connection with the connection body, and therefore low losses and high signal integrity. Advantageously, an additional formation of solder balls or the like may be dispensable between the design layer 102 with its low ohmic solderable protrusions 212 and the connection body.

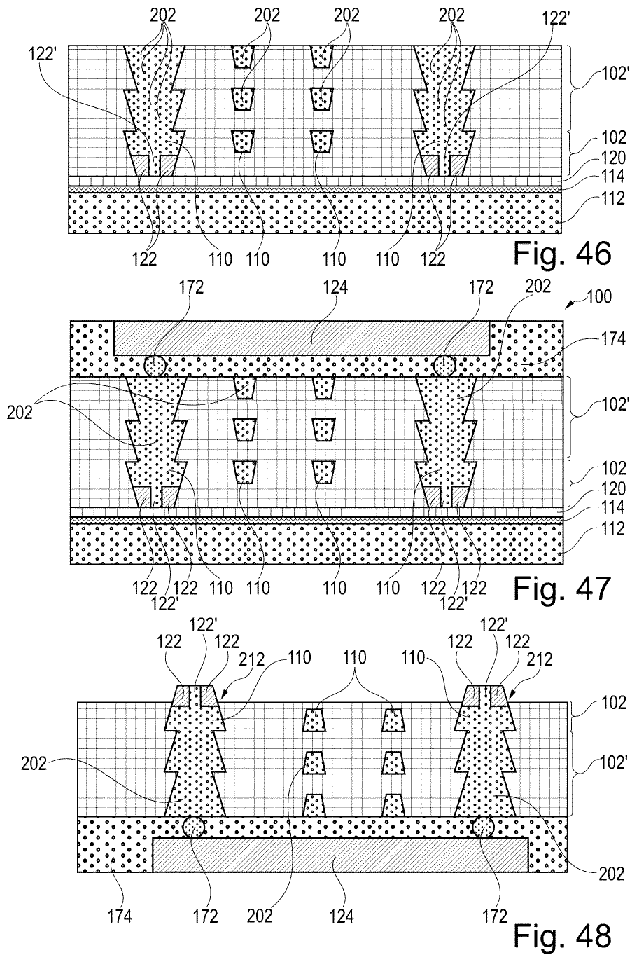

FIG. 50 illustrates a component carrier 100 according to yet another exemplary embodiment of the disclosure. In this embodiment, a laminated printed circuit board layer stack 131 is connected with the stack of design layers 102, 102′, more precisely to an uppermost exposed design layer 102′. Protruding or embedded solder caps provided by solderable metallic material of the metallic base structure 122 alone may be used for establishing a solder connection between the metal-filled design layer 102 and a connection body, in the shown example an electronic component 124.

For example, the illustrated electroplating structure 110 may be an integrated wiring structure (see reference signs 164, 166, 168 described above).

At the illustrated solder structures 172, at least one further body such as at least one component 124 and/or a mounting base 137 may be connected (not shown).

Briefly, FIG. 50 shows an embodiment with IC substrate or PCB structures connected with NIL-type redistribution layer and a component attached by using tin caps.

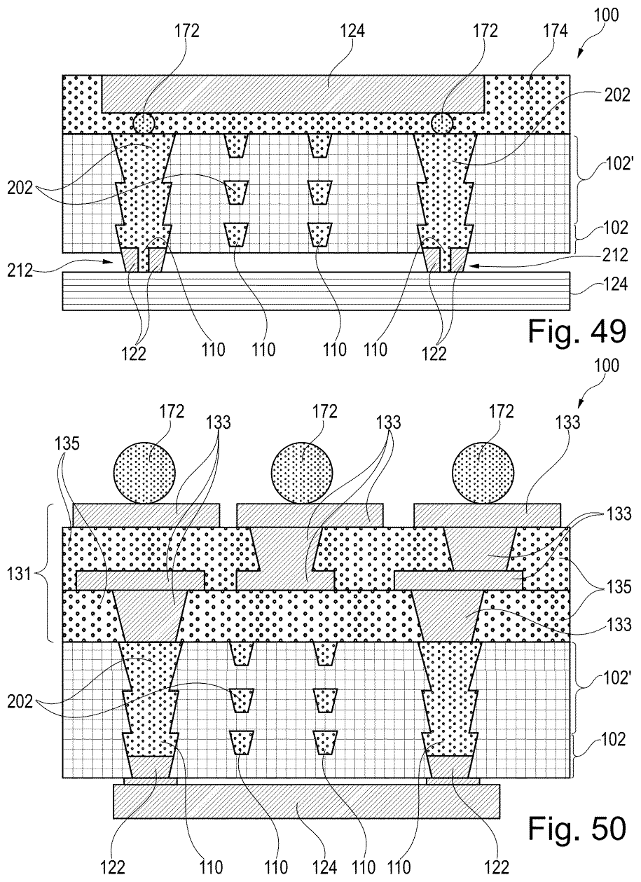

FIG. 51 illustrates a component carrier 100 according to yet another exemplary embodiment of the disclosure.

The component carrier 100 of FIG. 51 comprises a mounting base 137, for example an IC substrate or a PCB. A design layer 102 having a stamped surface profile comprises an electrically conductive seed layer (not illustrated in FIG. 51, compare for instance FIG. 43 or FIG. 18) selectively lining at least part of indentations 108 of the stamped design layer 102, an electroplating structure 110 selectively on or above separated portions of the seed layer 118 and optionally but preferably a metallic base structure 122, 122′ (not shown in FIG. 51). Said metallic constituents may form a redistribution structure 214 integrated in the design layer 102.

Furthermore, the illustrated component carrier 100 comprises a further design layer 102′ on the design layer 102. As shown, a further surface profile is stamped in the further design layer 102 for forming further indentations 216 to thereby expose part of the electroplating structure 110. Advantageously, the NIL-type further design layer 102′ is thus configured as solder mask defining solderable and non-solderable surface portions of the component carrier 100. Thus, the electroplating structure 110 beneath the further design layer 102′ can be advantageously used as a redistribution structure or as part thereof. This promotes a compact design.

As shown as well in FIG. 51, a surface finish 204 (for instance ENIG) may be formed in the further indentations 216 and on the exposed electroplating structure 110.

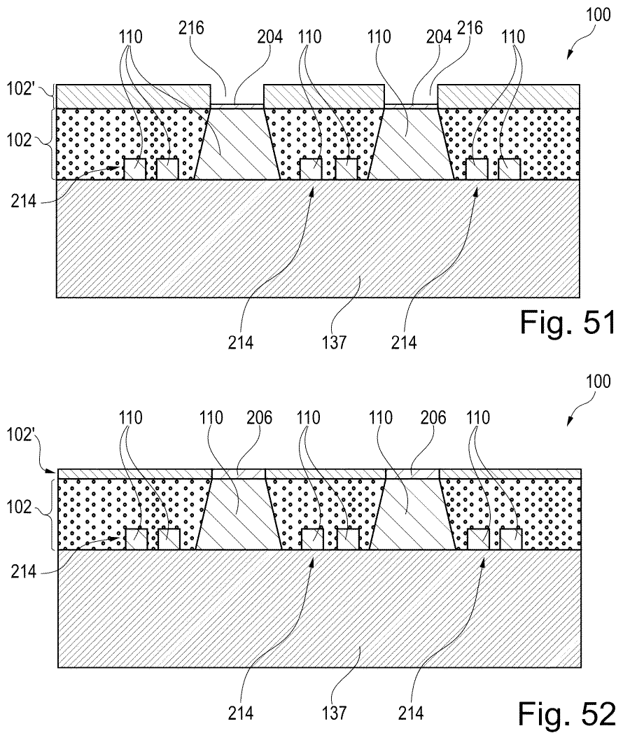

FIG. 52 illustrates a component carrier 100 according to yet another exemplary embodiment of the disclosure.

A difference between the embodiment of FIG. 52 and the embodiment of FIG. 51 is that, according to FIG. 52, a solderable metallic structure 206 (for instance made of tin) is formed in the further indentations 216 of the further design layer 102′ and on the exposed surface of the electroplating structure 110. This prepares the component carrier 100 of FIG. 52 perfectly for a subsequent solder connection with another connection body (not shown).

Still referring to FIG. 52, the further design layer 102′ may also be configured to function as an underfill. Such an NIL-based or NIL-printed underfill may be still sticky at the manufacturing stage of FIG. 52.

In particular, it may be possible to configure the further design layer 102′ to function as both, solder mask and underfill. Further advantageously, the further design layer 102′ may be configured to provide also a cooling function and/or a heat spreading function. In yet another configuration, the further design layer 102′ may also be configured so as to be anti-adhesive, for example for providing a Lotus effect.

A person skilled in the art will understand that the illustrated embodiments may omit certain features of component carriers for the sake of conciseness and for the sake of clarity. For example, further layers may be added, and finishing stages such as formation of a solder mask may be carried out although not described herein.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A method of manufacturing a component carrier, comprising:
stamping a surface profile in a design layer;
forming an electrically conductive seed layer on the stamped design layer;
forming a patterned electroplating protection structure on portions of the seed layer apart from indentations of the profiled design layer; and
electroplating an electroplating structure selectively on or above portions of the seed layer exposed with respect to the electroplating protection structure.

2. The method according to claim 1, comprising at least one of the following features:
wherein the stamping comprises forming tapering indentations in the design layer;
wherein the stamping comprises forming indentations of different depth and/or different length in the design layer;
wherein the stamping comprises forming trace-shaped and/or via-shaped and/or combined trace-and-via-shaped indentations in the design layer;
wherein the method comprises configuring the design layer as a Nanoimprint Lithography layer;
wherein the method comprises curing the design layer;
wherein the method comprises removing the electroplating protection structure after the electroplating;
wherein the method comprises removing portions of the seed layer which have been exposed as a result of the removing of the electroplating protection structure;
wherein the method comprises:
forming the design layer on or above a carrier, comprising or consisting of glass, covered with a release layer; and
detaching the profiled design layer with sections of the seed layer and the electroplating structure from the carrier at the release layer;
wherein the method comprises forming a build-up based on the detached profiled design layer with sections of the seed layer and the electroplating structure;
wherein the method comprises forming a build-up on the profiled design layer with sections of the seed layer and the electroplating structure;
wherein the method comprises applying an adhesion promoter and/or a barrier layer on the stamped design layer before forming the electrically conductive seed layer;
wherein the method comprises removing residues of the design layer in at least one bottom region of the indentations of the profiled design layer;
wherein the method comprises arranging, stamping, and etching the design layer on an electrically conductive layer so that at least one surface portion of the electrically conductive layer is exposed with respect to the stamped design layer;
wherein the method comprises forming a metallic base structure in the corresponding at least one indentation of the profiled design layer;
wherein the method comprises removing the design layer before completing manufacture of the component carrier.

3.-14. (canceled)

15. The method according to claim 1, wherein the method comprises arranging and stamping, and additionally etching, the design layer on an electrically conductive layer so that at least one surface portion of the electrically conductive layer is exposed with respect to the stamped design layer,
wherein the method comprises forming a metallic base structure selectively on the at least one exposed surface portion of the electrically conductive layer and in the corresponding at least one indentation of the profiled design layer.

16. The method according to claim 15, comprising at least one of the following features:
wherein the method comprises subsequently electroplating the electroplating structure on or above the metallic base structure;
wherein the method comprises forming the metallic base structure to comprise a bottom-sided sub-structure and a top-sided substructure;
wherein the method comprises forming at least part of the metallic base structure by electroplating;
wherein the method comprises forming the metallic base structure at least partially from a solderable metallic material comprising tin.

17.-20. (canceled)

21. The method according to claim 16, comprising at least one of the following features:
wherein the method comprises forming the solderable metallic material on at least part of a bottom surface of the at least one indentation of the profiled design layer;
wherein the method comprises forming the metallic base structure partially from the solderable metallic material and partially from a metal with a higher electric conductivity than the solderable metallic material;
wherein the method comprises forming the solderable metallic material and the metal with the higher electric conductivity both on at least part of a bottom surface of the corresponding at least one indentation of the profiled design layer, so that the solderable metallic material at least partially laterally surrounds the metal with the higher electric conductivity;
wherein the method comprises detaching the profiled design layer together with the metallic base structure from a carrier to thereby expose the solderable metallic material;
wherein the method comprises creating a solder connection between the exposed solderable metallic material and a connection body, a mounting base or a component.

22.-25. (canceled)

26. The method according to claim 1, wherein the method comprises:
forming a further design layer on or above the design layer;
stamping a further surface profile in the further design layer for forming at least one further indentation to thereby expose at least part of the electroplating structure; and
configuring the further design layer as solder mask and/or underfill.

27. The method according to claim 26, wherein the method comprises configuring at least part of the electroplating structure beneath the further design layer as a redistribution structure or as part thereof,
wherein the method comprises forming a surface finish and/or a solderable metallic structure in the at least one further indentation and on or above the exposed electroplating structure.

28.-29. (canceled)

30. A component carrier, comprising:
a design layer having a stamped surface profile;
an electrically conductive seed layer selectively lining indentations of the stamped design layer; and
an electroplating structure selectively on or above separated portions of the seed layer.

31. The component carrier according to claim 30, comprising at least one of the following features:
wherein the electroplating structure forms or forms part of electrically conductive sub-structures of different depth and/or different length in the design layer;
wherein the electroplating structure forms or forms part of electrically conductive trace-type and/or via-type sub-structures;
wherein the electroplating structure forms or forms part of at least one electrically conductive sub-structure having a depth-to-diameter ratio of larger than 1;
wherein the electroplating structure has tapering sidewalls;
wherein a roughness Ra of a sidewall surface of the design layer delimiting the surface profile is not more than 100 nm;
wherein the design layer is arranged on an electrically conductive layer so that at least one surface portion of the electrically conductive layer is exposed with respect to the design layer at at least one of the indentations;
wherein the component carrier comprises a build-up on one or both opposing sides of the profiled design layer with the portions of the seed layer and the electroplating structure, wherein the build-up comprises at least one laminated printed circuit board layer stack;
comprising at least one component being electrically connected to the electroplating structure;
further comprising a further design layer having a further stamped surface profile, a further electrically conductive seed layer selectively lining further indentations of the stamped further design layer, and a further electroplating structure selectively on or above separated portions of the further seed layer, wherein the further profiled design layer with the further electrically conductive seed layer and the further electroplating structure are arranged on, and are electrically coupled with, the profiled design layer with the electrically conductive seed layer and the electroplating structure, forming a forming a multi-layer redistribution structure, wherein the further electrically conductive seed layer and the further electroplating structure are connected in a landless way with the electrically conductive seed layer and the electroplating structure, wherein one main surface of the design layer has a higher surface roughness Ra than a corresponding main surface of the at least one further design layer, and wherein said one main surface faces away from the stamped surface profile of the design layer;
the component carrier comprises a component mounted on the design layer by a connection structure, by one of a solder structure and a thermal compression bonding structure, arranged between the component and the design layer;
wherein the electroplating structure comprises three-dimensionally curved substructures;
wherein the indentations of the stamped design layer are at least partially filled with at least one wiring structure of the group consisting of: a wiring structure having a bottom portion constituted by a bottom-sided portion of a metal base structure, wherein a top-sided portion of the metal base structure is formed directly on the bottom-sided portion, wherein a remaining volume of the wiring structure is lined with a portion of the seed layer covering a top surface of the metal base structure as well as an exposed sidewall of the design layer, and wherein a remaining volume of the wiring structure delimited by the portion of the seed layer is filled with at least a portion of the electroplating structure; a wiring structure having a portion of the seed layer lining exposed sidewalls and an exposed bottom surface of the design layer, wherein a remaining volume of the wiring structure is filled with at least a portion of the electroplating structure; a wiring structure having a bottom portion constituted by a bottom-sided portion of a metal base structure, wherein a top-sided portion of the metal base structure is formed directly on the bottom-sided portion, wherein a remaining volume of the wiring structure is lined with a portion of the seed layer covering a top surface of the metal base structure as well as an exposed sidewall and an exposed horizontal wall of the design layer, wherein a remaining volume of the wiring structure delimited by the portion of the seed layer is filled with at least a portion of the electroplating structure, and wherein the assigned indentation has a step;
the component carrier comprises a build-up on one or both opposing sides of the profiled design layer, wherein the build-up comprises at least one laminated printed circuit board layer stack;
wherein the electroplating structure protrudes beyond the design layer;
the component carrier comprises at least one of the following features: wherein the design layer has an adhesion of more than 600 Nm; wherein the design layer has a temperature resistance between 200° C. and 300° C.; wherein the design layer comprises material of a flame retardancy class 4; wherein the design layer comprises material having a glass-transition temperature between 120° C. and 200° C.; wherein the design layer has a Modulus below a glass-transition temperature of 1000 MPa to 14000 MPa; wherein the design layer has a Modulus above a glass-transition temperature of 60 MPa to 800 MPa; wherein the design layer has a thermal expansion coefficient below a glass-transition temperature of 10 ppm/K to 40 ppm/K; wherein the design layer has a thermal expansion coefficient above a glass-transition temperature of 50 ppm/K to 100 ppm/K;
wherein the design layer is formed with the at least one of the following properties: a fracture strain below a glass-transition temperature of at least 2%, a chemical shrinkage below 3%, a moisture absorption below 0.1%, and a desmear rate of more than 0.006 g/min; wherein the design layer comprises a fully cured polymer based on at least one of the following group comprising epoxies, acrylates, polyphenylenether, polyimide, polyamide, polyetheretherketon poly(p-phenylene ether) (PPE), Bisbenzocyclobutene (BCB), and/or Polybenzoxabenzole (PBO);
wherein the design layer comprises a prepolymer having at least one photoinitiator, contained in an amount of 0.1 wt. % to 10 wt. %;
wherein the design layer has a viscosity of 0.01 Pas to 1 Pas;
wherein the component carrier comprises a metallic base structure in a respective indentation and connected with the electroplating structure.

32.-36. (canceled)

37. The component carrier according to claim 30, comprising a metallic base structure in a bottom of a corresponding indentation of the design layer.

38. The component carrier according to claim 37, comprising at least one of the following features:
wherein at least a portion of the electroplating structure is arranged on top of the metallic base structure;
wherein the metallic base structure comprises a bottom-sided sub-structure and a top-sided substructure;
wherein at least part of the metallic base structure is electroplated.

39.-46. (canceled)

47. The component carrier according to claim 30, comprising two components arranged side-by-side at least partially on the design layer and being electrically coupled with each other by electrically conductive connection structures at and/or lateral from the design layer.

48. The component carrier according to claim 47,
wherein at least one of the two components comprises pads having different pitch sizes being electrically coupled with the electrically conductive connection structures having different pitch sizes by connection structures.

49. The component carrier according to claim 48,
wherein at least one first pad of the pads has a smaller pitch size than at least one second pad of the pads having a larger pitch size;
wherein the at least one first pad is electrically coupled with at least one first of the electrically conductive connection structures on the design layer; and
wherein the at least one second pad is electrically coupled with at least one second of the electrically conductive connection structures on a laminated printed circuit board layer stack apart from the design layer.

50.-56. (canceled)

57. The component carrier according to claim 30, wherein the design layer comprises polymer- or oligomer-based building blocks, wherein at least one of the building blocks is based on one of epoxies, acrylates, polyphenylenether, polyimide, polyamide, polyetheretherketon poly(p-phenylene ether), (PPE), Bisbenzocyclobutene (BCB), and/or Polybenzoxabenzole (PBO).

58. The component carrier according to claim 57, wherein at least one of the building blocks has at least one functional group covalently bonded to another one of the least one building block, wherein the at least one functional group is selected from one of the group consisting of: a thiol group selected from the group of 3-mercaptopropionates, 3-mercaptoacetates, thioglycolates and alkylthiols, and/or a double bond selected from the group of acrylates, methyl acrylates, vinyl ethers, allyl ethers, propenyl ethers, alkenes, dienes, unsaturated esters and allyl triazines, allyl isocyanates and N-vinyl amides.

59.-60. (canceled)

61. The component carrier according to claim 30, wherein the design layer a fully cured resin, wherein the design layer further comprises filler particles in an amount of 1 wt. % to 10 wt. %.

62. The component carrier according to claim 61, comprising at least one of the following features:
wherein the chloride content of the resin is below 30 ppm;
wherein the filler particles comprise inorganic fillers, wherein the inorganic fillers are in a crystalline state and encapsulated;
wherein the filler particles have a size of less than 0.1 μm;
wherein the filler particles comprise Talcum, Zeolite or fused SiO₂;
wherein the filler particles are of plasma etchable material;
wherein the design layer comprises less than 95% filler particles.

63.-69. (canceled)

70. The component carrier according to claim 69, comprising a metallic base structure in a respective indentation and connected with the electroplating structure, wherein the metallic base structure comprises a solderable metallic material, comprising or consisting of tin,
wherein the metallic base structure is formed partially from the solderable metallic material and partially from a metal with a higher electric conductivity than the solderable metallic material,
wherein the solderable metallic material at least partially laterally surrounds the metal with the higher electric conductivity, and
wherein the component carrier comprises a connection body, a mounting base or a component soldered on the solderable metallic material.

71.-73. (canceled)

74. The component carrier according to claim 30, comprising a further design layer configured as a solder mask and/or underfill, arranged on or above the design layer and having a further stamped surface profile forming at least one further indentation to thereby expose at least part of the electroplating structure.

75. The component carrier according to claim 74, further comprising at least one of the following features:
wherein at least part of the electroplating structure beneath the solder mask and/or underfill is configured as a redistribution structure;
wherein the component carrier comprises a surface finish and/or a solderable metallic structure in the at least one further indentation and on or above the exposed electroplating structure;
wherein one main surface of the design layer has a higher surface roughness Ra than a corresponding main surface of the at least one further design layer, wherein said one main surface faces away from the stamped surface profile of the design layer.

76. (canceled)

77. A component carrier, comprising:
a mounting base and/or one or more components;
a laminated layer stack mounted on or above the mounting base and/or on or above the one or more components;
at least one design layer each having a stamped surface profile with indentations filled at least partially with an integrated wiring structure functioning as redistribution structure, wherein the at least one design layer is formed on the laminated layer stack; and
one or more surface mounted components on the at least one design layer.

78. The component carrier according to claim 77, further comprising at least one of the following features:
wherein the mounting base is a motherboard, a printed circuit board or an integrated circuit substrate;
wherein the laminated layer stack is a printed circuit board, an integrated circuit substrate or an interposer;
wherein the one or more surface mounted components are electrically connected to the at least one design layer by solder structures;
wherein the one or more surface mounted components are encapsulated in a mold compound;
wherein the at least one design layer is a stack of design layers;
wherein the component carrier is configured as a hybrid package;
wherein the integration density of wiring structures in the at least one design layer is larger than in the laminated layer stack;
wherein the component carrier comprises at least one further design layer having a stamped surface profile with indentations filled at least partially with a further integrated wiring structure, wherein the at least one further design layer is formed between the mounting base and/or the one or more components and the laminated layer stack;
wherein one main surface of the design layer has a higher surface roughness Ra than a corresponding main surface of the at least one further design layer; and
wherein said one main surface faces away from the stamped surface profile of the design layer.

79.-87. (canceled)
